(19) United States
(12) Patent Application Publication
(10) Pub. No.: US 2026/0156935 A1
(43) Pub. Date: Jun. 4, 2026

(54) INTEGRATED CIRCUIT DEVICE

(71) Applicant: Samsung Electronics Co., Ltd., Suwon-si, Gyeonggi-do (KR)

(72) Inventors: Jieun HAN, Suwon-si (KR); Hyonwook RA, Suwon-si (KR); Kwangyong YANG, Suwon-si (KR); Wonhee JEONG, Suwon-si (KR); Heeeun JOO, Suwon-si (KR)

(73) Assignee: Samsung Electronics Co., Ltd., Suwon-si, Gyeonggi-do (KR)

(21) Appl. No.: 19/238,829

(22) Filed: Jun. 16, 2025

(30) Foreign Application Priority Data
Dec. 4, 2024 (KR) 10-2024-0178884

(51) Int. Cl. H10D 84/90; H10D 89/10

(52) U.S. Cl. CPC H10D 84/964; H10D 84/929; H10D 84/953; H10D 89/10

(57) ABSTRACT

An integrated circuit device includes a first fin-type active region protruding from a substrate and extending in a first horizontal direction; a first source/drain region on the first fin-type active region; a first source/drain contact on and electrically connected to the first source/drain region; a first contact isolation insulating structure extending in a second horizontal direction, and including a first contact isolation insulating pattern and a first isolation insulating liner, the first contact isolation insulating pattern contacting the first source/drain contact, and the first isolation insulating liner covering sidewalls of the first contact isolation insulating pattern in the first horizontal direction and a lower surface of the first contact isolation insulating pattern; and a second isolation insulating liner covering only first sidewalls of the first source/drain contact in the first horizontal direction. A constituent material of the first and second isolation insulating liners include a same material.

### CROSS-REFERENCE TO RELATED APPLICATION

This application is based on and claims priority under 35 U.S.C. § 119 to Korean Patent Application No. 10-2024-0178884, filed on Dec. 4, 2024, in the Korean Intellectual Property Office, the disclosure of which is incorporated by reference herein in its entirety.

### BACKGROUND

The inventive concepts relate to integrated circuit devices, and more particularly, to integrated circuit devices including a field-effect transistor.

Due to the advance in electronics technology, integrated circuit devices have been rapidly down-scaled. Because highly down-scaled integrated circuit devices having high operation speeds and accuracy in operations are advantageous, there is a desire to provide wiring structures having stable and optimized structures in relatively small areas.

### SUMMARY

The inventive concepts provide an integrated circuit device having a structure capable of improving the reliability thereof when the integrated circuit device has a device area reduced due to down-scaling.

Some example embodiments of the inventive concepts provide an integrated circuit device that includes a first fin-type active region protruding from a substrate and extending in a first horizontal direction; a first source/drain region on the first fin-type active region; a first source/drain contact on the first source/drain region and electrically connected to the first source/drain region; a first contact isolation insulating structure extending along a straight line with the first source/drain contact in a second horizontal direction perpendicular to the first horizontal direction, the first contact isolation insulating structure including a first contact isolation insulating pattern and a first isolation insulating liner, the first contact isolation insulating pattern contacting the first source/drain contact, and the first isolation insulating liner covering sidewalls of the first contact isolation insulating pattern in the first horizontal direction, and the first isolation insulating liner covering a lower surface of the first contact isolation insulating pattern; and a second isolation insulating liner covering only first sidewalls of the first source/drain contact in the first horizontal direction from among the first sidewalls of the first source/drain contact in the first horizontal direction and second sidewalls of the first source/drain contact in the second horizontal direction. A constituent material of the first isolation insulating liner and a constituent material of the second isolation insulating liner include a same constituent material.

Some example embodiments of the inventive concepts further provide an integrated circuit device that includes a plurality of fin-type active regions protruding from a substrate and extending lengthwise in a first horizontal direction, the plurality of fin-type active regions being apart from each other in a second horizontal direction that is perpendicular to the first horizontal direction; a plurality of source/drain regions respectively on the plurality of fin-type active regions and aligned in a row on a first straight line extending along the second horizontal direction; a plurality of source/drain contacts electrically connected to at least one source/drain region from the plurality of source/drain regions, the plurality of source/drain contacts being aligned in a row along the first straight line; a plurality of contact isolation insulating structures respectively between the plurality of source/drain contacts and aligned in a row along the first straight line, each of the plurality of contact isolation insulating structures including a contact isolation insulating pattern and a first isolation insulating liner, the contact isolation insulating pattern having a sidewall contacting a source/drain contact from among the plurality of source/drain contacts that is adjacent to the contact isolation insulating pattern in the second horizontal direction, and the first isolation insulating liner covering sidewalls of the contact isolation insulating pattern in the first horizontal direction and a lower surface of the contact isolation insulating pattern; and a plurality of second isolation insulating liners respectively covering only first sidewalls of each of the plurality of source/drain contacts in the first horizontal direction from among the first sidewalls of each of the plurality of source/drain contacts in the first horizontal direction and second sidewalls of each of the plurality of source/drain contacts in the second horizontal direction. The first isolation insulating liner of each of the plurality of contact isolation insulating structures and each of the plurality of second isolation insulating liners include a same constituent material.

Some example embodiments of the inventive concepts still further provide an integrated circuit device that includes a plurality of fin-type active regions protruding from a substrate and extending lengthwise in a first horizontal direction, the plurality of fin-type active regions being apart from each other in a second horizontal direction that is perpendicular to the first horizontal direction; a plurality of nanosheet stacks over each of the plurality of fin-type active regions, each of the plurality of nanosheet stacks including at least one nanosheet; a pair of gate lines over the plurality of fin-type active regions and extending lengthwise in the second horizontal direction across the plurality of fin-type active regions parallel to each other, gate lines of the pair of gate lines surrounding the at least one nanosheet of at least one nanosheet stack from the plurality of nanosheet stacks; a plurality of source/drain regions respectively on the plurality of fin-type active regions between the pair of gate lines, the plurality of source/drain regions being aligned in a row on a first straight line extending along the second horizontal direction; a plurality of source/drain contacts each electrically connected to at least one source/drain region from the plurality of source/drain regions, the plurality of source/drain contacts being aligned in a row along the first straight line; a plurality of contact isolation insulating structures respectively between the plurality of source/drain contacts and aligned in a row along the first straight line, each of the plurality of contact isolation insulating structures including a contact isolation insulating pattern and a first isolation insulating liner, the contact isolation insulating pattern having a sidewall contacting a source/drain contact from among the plurality of source/drain contacts that is adjacent to the contact isolation insulating pattern in the second horizontal direction, and the first isolation insulating liner covering sidewalls of the contact isolation insulating pattern in the first horizontal direction and a lower surface of the contact isolation insulating pattern; and a plurality of second isolation insulating liners respectively covering only first sidewalls of each of the plurality of source/drain contacts in the first horizontal direction from among the first sidewalls of each of the plurality of source/drain contacts in the first horizontal direction and second sidewalls of each of the plurality of source/drain contacts in the second horizontal direction. The first isolation insulating liner of each of the plurality of contact isolation insulating structures and each of the plurality of second isolation insulating liners include a same constituent material, the same constituent material including silicon nitride, silicon oxide, SiOC, SiOCN, SiCN, SiBN, SiON, SiBCN, SiOF, SiOCH, or a combination thereof.

Some example embodiments of the inventive concepts further provide a method of manufacturing an integrated circuit device that includes forming a first fin-type active region protruding from a substrate and extending in a first horizontal direction; forming a first source/drain region on the first fin-type active region; forming a first source/drain contact on the first source/drain region and electrically connected to the first source/drain region; forming a first contact isolation insulating structure extending along a straight line with the first source/drain contact in a second horizontal direction perpendicular to the first horizontal direction, the forming of the first contact isolation insulating structure including forming a first contact isolation insulating pattern contacting the first source/drain contact, and forming a first isolation insulating liner covering sidewalls of the first contact isolation insulating pattern in the first horizontal direction and covering a lower surface of the first contact isolation insulating pattern; and forming a second isolation insulating liner covering only first sidewalls of the first source/drain contact in the first horizontal direction from among the first sidewalls of the first source/drain contact in the first horizontal direction and second sidewalls of the first source/drain contact in the second horizontal direction. A constituent material of the first isolation insulating liner and a constituent material of the second isolation insulating liner include a same constituent material.

In some example embodiments of the method of manufacturing the integrated circuit device, in the first horizontal direction, a first width of the first source/drain contact is less than a second width of the first contact isolation insulating structure.

In some example embodiments, the method of manufacturing the integrated circuit device further includes forming a device isolation film covering sidewalls of the first fin-type active region; and forming an insulating structure covering the device isolation film. The forming of first source/drain contact includes forming a lower portion of the source/drain contact, and in a cross-sectional view of the first source/drain contact taken in the first horizontal direction, a first distance between the lower portion and the device isolation film is less than a second distance between the second isolation insulating liner and the device isolation film, and the lower portion of the first source/drain contact is over the device isolation film and contacts the insulating structure.

In some example embodiments, the method of manufacturing the integrated circuit device further includes forming a device isolation film covering sidewalls of the first fin-type active region; and forming an insulating structure covering the device isolation film and a portion of the first source/drain region. The first isolation insulating liner of the first contact isolation insulating structure contacts the insulating structure at a position overlapping the device isolation film in a vertical direction, and the first contact isolation insulating pattern of the first contact isolation insulating structure is apart from the insulating structure with the first isolation insulating liner therebetween.

In some example embodiments of the method of manufacturing the integrated circuit device, the first contact isolation insulating structure has a surface facing the insulating structure, and the surface facing the insulating structure has a convex shape toward the device isolation film.

In some example embodiments, the method of manufacturing the integrated circuit device further includes forming a metal silicide film between the first source/drain region and the first source/drain contact; and the forming of the first source/drain contact includes forming the first source/drain contact as including a contact tail between the first source/drain region and the first contact isolation insulating structure, the contact tail extending in a vertical direction toward the substrate along a surface of the first contact isolation insulating structure; and the forming of the metal silicide film includes forming a portion of the metal silicide film between the contact tail and the first source/drain region.

In some example embodiments, the method of manufacturing the integrated circuit device further includes forming a second fin-type active region protruding from the substrate and extending in the first horizontal direction parallel to the first fin-type active region; forming a second source/drain region on the second fin-type active region, the second source/drain region being apart from the first source/drain region in the second horizontal direction; and forming a second source/drain contact on the second source/drain region and electrically connected to the second source/drain region, the second source/drain contact being apart from the first source/drain contact in the second horizontal direction with the first contact isolation insulating structure therebetween. The first source/drain contact, the first contact isolation insulating structure, and the second source/drain contact extend along the second horizontal direction. The forming of the first contact isolation insulating pattern includes forming a first sidewall, in the second horizontal direction, of the first contact isolation insulating pattern of the first contact isolation insulating structure in contact with the first source/drain contact, and forming a second sidewall of the first contact isolation insulating pattern in the second horizontal direction in contact with the second source/drain contact.

In some example embodiments, the method of manufacturing the integrated circuit device further includes forming a device isolation film covering sidewalls of the first fin-type active region; forming an insulating structure covering the device isolation film; forming a gate line over the first fin-type active region and the device isolation film, the gate line extending in the second horizontal direction and intersecting the first fin-type active region; forming a second source/drain region on the first fin-type active region and apart from the first source/drain region in the first horizontal direction with the gate line therebetween; and forming a second source/drain contact overlapping the second source/drain region and the device isolation film in a vertical direction, the second source/drain contact being electrically connected to the second source/drain region. A first distance between a lowermost surface of a portion of the second source/drain contact which overlaps the device isolation film in the vertical direction and the device isolation film is less than a second distance between a lowermost surface of a portion of the first contact isolation insulating structure which overlaps the device isolation film in the vertical direction and the device isolation film.

In some example embodiments, the method of manufacturing the integrated circuit device further forming a third isolation insulating liner covering only third sidewalls of the second source/drain contact in the first horizontal direction from among the third sidewalls of the second source/drain contact in the first horizontal direction and fourth sidewalls of the second source/drain contact in the second horizontal direction. A constituent material of the third isolation insulating liner is a same constituent material as the constituent material of each of the first isolation insulating liner and the second isolation insulating liner.

In some example embodiments, the method of manufacturing the integrated circuit device further includes forming a gate line over the first fin-type active region, the gate line extending in the second horizontal direction and intersecting the first fin-type active region; forming a second source/drain region on the first fin-type active region and apart from the first source/drain region with the gate line therebetween; and forming a second contact isolation insulating structure overlapping the second source/drain region in a vertical direction. A first length in the vertical direction of the second source/drain region on the first fin-type active region is greater than a second length in the vertical direction of the first source/drain region on the first fin-type active region.

In some example embodiments of the method of manufacturing the integrated circuit device, in the vertical direction, a first distance between the second contact isolation insulating structure and the first fin-type active region which are apart from each other with the second source/drain region therebetween, is greater than a second distance between the first source/drain contact and the first fin-type active region which are apart from each other with the first source/drain region therebetween.

In some example embodiments of the method of manufacturing the integrated circuit device, the forming of the second contact isolation insulating structure includes forming a second contact isolation insulating pattern and a third isolation insulating liner, the second contact isolation insulating pattern being apart from the second source/drain region, and the third isolation insulating liner covering a lower surface of the second contact isolation insulating pattern which faces the second source/drain region and sidewalls of the second contact isolation insulating pattern in the first horizontal direction. A constituent material of the third isolation insulating liner is a same constituent material as the constituent material of each of the first isolation insulating liner and the second isolation insulating liner.

Some example embodiments of the inventive concepts still further provide a method of manufacturing an integrated circuit device that includes forming a plurality of fin-type active regions protruding from a substrate and extending lengthwise in a first horizontal direction, the plurality of fin-type active regions being apart from each other in a second horizontal direction that is perpendicular to the first horizontal direction; forming a plurality of source/drain regions respectively on the plurality of fin-type active regions and aligned in a row on a first straight line extending along the second horizontal direction; forming a plurality of source/drain contacts electrically connected to at least one source/drain region from the plurality of source/drain regions, the plurality of source/drain contacts being aligned in a row along the first straight line; forming a plurality of contact isolation insulating structures respectively between the plurality of source/drain contacts and aligned in a row along the first straight line, the forming of the plurality of contact isolation insulating structures includes forming a contact isolation insulating pattern and a first isolation insulating liner, the contact isolation insulating pattern having a sidewall contacting a source/drain contact from among the plurality of source/drain contacts that is adjacent to the contact isolation insulating pattern in the second horizontal direction, and the first isolation insulating liner covering sidewalls of the contact isolation insulating pattern in the first horizontal direction and a lower surface of the contact isolation insulating pattern; and forming a plurality of second isolation insulating liners respectively covering only first sidewalls of each of the plurality of source/drain contacts in the first horizontal direction from among the first sidewalls of each of the plurality of source/drain contacts in the first horizontal direction and second sidewalls of each of the plurality of source/drain contacts in the second horizontal direction. The first isolation insulating liner of each of the plurality of contact isolation insulating structures and each of the plurality of second isolation insulating liners include a same constituent material.

Some example embodiments further provide a method of manufacturing an integrated circuit device that includes forming a plurality of fin-type active regions protruding from a substrate and extending lengthwise in a first horizontal direction, the plurality of fin-type active regions being apart from each other in a second horizontal direction that is perpendicular to the first horizontal direction; forming a plurality of nanosheet stacks over each of the plurality of fin-type active regions, each of the plurality of nanosheet stacks comprising at least one nanosheet; forming a pair of gate lines over the plurality of fin-type active regions and extending lengthwise in the second horizontal direction across the plurality of fin-type active regions parallel to each other, gate lines of the pair of gate lines surrounding the at least one nanosheet of at least one nanosheet stack from the plurality of nanosheet stacks; forming a plurality of source/drain regions respectively on the plurality of fin-type active regions between the pair of gate lines, the plurality of source/drain regions being aligned in a row on a first straight line extending along the second horizontal direction; forming a plurality of source/drain contacts each electrically connected to at least one source/drain region from the plurality of source/drain regions, the plurality of source/drain contacts being aligned in a row along the first straight line; forming a plurality of contact isolation insulating structures respectively between the plurality of source/drain contacts and aligned in a row along the first straight line, the forming of the plurality of contact isolation insulating structures including forming a contact isolation insulating pattern and a first isolation insulating liner, the contact isolation insulating pattern having a sidewall contacting a source/drain contact from among the plurality of source/drain contacts that is adjacent to the contact isolation insulating pattern in the second horizontal direction, and the first isolation insulating liner covering sidewalls of the contact isolation insulating pattern in the first horizontal direction and a lower surface of the contact isolation insulating pattern; and forming a plurality of second isolation insulating liners respectively covering only first sidewalls of each of the plurality of source/drain contacts in the first horizontal direction from among the first sidewalls of each of the plurality of source/drain contacts in the first horizontal direction and second sidewalls of each of the plurality of source/drain contacts in the second horizontal direction. The first isolation insulating liner of each of the plurality of contact isolation insulating structures and each of the plurality of second isolation insulating liners include a same constituent material.

In some example embodiments of the method of manufacturing the integrated circuit device, the same constituent material includes silicon nitride, silicon oxide, SiOC, SiOCN, SiCN, SiBN, SiON, SiBCN, SiOF, SiOCH, or a combination thereof.

### BRIEF DESCRIPTION OF THE DRAWINGS

Some example embodiments will be more clearly understood from the following detailed description taken in conjunction with the accompanying drawings in which:

FIG. 1 is a schematic plan view of an example of a cell block of an integrated circuit device according to some example embodiments;

FIG. 2 is a planar layout diagram illustrating an integrated circuit device according to some example embodiments;

FIG. 3 is a cross-sectional view of the integrated circuit device of FIG. 2, taken along a line X1-X1′ of FIG. 2;

FIG. 4 is a cross-sectional view of the integrated circuit device of FIG. 2, taken along a line X2-X2′ of FIG. 2;

FIG. 5 is a cross-sectional view of the integrated circuit device of FIG. 2, taken along a line Y1-Y1′ of FIG. 2;

FIG. 6 is a cross-sectional view of the integrated circuit device of FIG. 2, taken along a line Y2-Y2′ of FIG. 2;

FIG. 7A is a planar layout diagram illustrating an integrated circuit device according to some example embodiments;

FIG. 7B is a cross-sectional view of the integrated circuit device of FIG. 7A, taken along a line X1-X1′ of FIG. 7A;

FIG. 8 is a cross-sectional view illustrating an integrated circuit device according to some example embodiments;

FIGS. 9A and 9B are cross-sectional views illustrating an integrated circuit device according to some example embodiments;

FIG. 10 is a block diagram of an integrated circuit device according to some example embodiments; and

FIGS. 11A to 26C are diagrams respectively illustrating a sequence of processes of a method of fabricating an integrated circuit device, according to some example embodiments, and in particular, FIGS. 11A, 12A, 14A, 15A, 16A, 17A, 18A, 19A, 20A, 21A, 22A, 23A, 24A, 25A, and 26A are cross-sectional views respectively illustrating cross-sectional structures of a region corresponding to a cross-section taken along the line X1-X1′ of FIG. 2, according to the sequence of processes, FIGS. 17B, 18B, 19B, 20B, 21B, 22B, 23B, 24B, 25B, and 26B are cross-sectional views respectively illustrating cross-sectional structures of a region corresponding to a cross-section taken along the line X2-X2′ of FIG. 2, according to the sequence of processes, FIGS. 11B, 12B, 13, 14B, 15B, 16B, 17C, 18C, 19C, 20C, 21C, 22C, 23C, 24C, 25C, and 26C are cross-sectional views respectively illustrating cross-sectional structures of a region corresponding to a cross-section taken along the line Y1-Y1′ of FIG. 2, according to the sequence of processes, and FIGS. 12C, 14C, 15C, 17D, and 18D are cross-sectional views respectively illustrating cross-sectional structures of a region corresponding to a cross-section taken along the line Y2-Y2′ of FIG. 2.

### DETAILED DESCRIPTION

Hereinafter, some example embodiments of the inventive concepts will be described in detail with reference to the accompanying drawings. Like components are denoted by like reference numerals throughout the specification, and repeated descriptions thereof are omitted.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

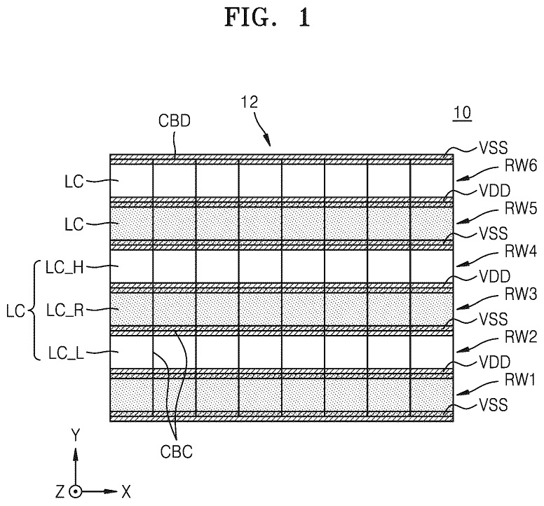

FIG. 1 is a schematic plan view of an example of a cell block 12 of an integrated circuit device 10 according to some example embodiments.

Referring to FIG. 1, the cell block 12 of the integrated circuit device 10 may include a plurality of cells LC including circuit patterns for constituting various circuits. The plurality of cells LC may be arranged in a matrix in a width direction (an X direction in FIG. 1) and a height direction (a Y direction in FIG. 1) in the cell block 12.

The plurality of cells LC may include a circuit pattern having a layout designed by a Place and Route (PnR) technique to perform at least one logical function. The plurality of cells LC may perform various logical functions. In some example embodiments, the plurality of cells LC may include a plurality of standard cells. In some example embodiments, at least some of the plurality of cells LC may perform the same logical function. In some example embodiments, at least some of the plurality of cells LC may respectively perform different logical functions.

The plurality of cells LC may include various types of logic cells including a plurality of circuit elements. For example, each of the plurality of cells LC may include, but is not limited to, an AND, a NAND, an OR, a NOR, an exclusive OR (XOR), an exclusive NOR (XNOR), an inverter (INV), an adder (ADD), a buffer (BUF), a delay (DLY), a filter (FIL), a multiplexer (MXT/MXIT), an OR/AND/INVERTER (OAI), an AND/OR (AO), an AND/OR/INVERTER (AOI), a D flip-flop, a reset flip-flop, a master-slave flip-flop, a latch, or a combination thereof.

In the cell block 12, at least some of the plurality of cells LC constituting one row (for example, RW1, RW2, RW3, RW4, RW5, or RW6) in the width direction (the X direction in FIG. 1) may have the same width. At least some of the plurality of cells LC constituting one row (for example, RW1, RW2, RW3, RW4, RW5, or RW6) may each have the same height. However, the inventive concepts are not limited to the example shown in FIG. 1, and at least some of the plurality of cells LC constituting one row (for example, RW1, RW2, RW3, RW4, RW5, or RW6) may have different widths and heights from each other.

The area of each of the plurality of cells LC in the cell block 12 of the integrated circuit device 10 may be defined by a cell boundary CBD. A cell interface portion CBC, at which respective cell boundaries CBD meet each other, may be arranged between two adjacent cells LC in the width direction (the X direction in FIG. 1) or the height direction (the Y direction in FIG. 1) from among the plurality of cells LC.

In some example embodiments, two adjacent cells LC in the width direction, among the plurality of cells LC constituting one row (for example, RW1, RW2, RW3, RW4, RW5, or RW6), may be in contact with each other at the cell interface portion CBC without a separation distance therebetween. In some example embodiments, two adjacent cells LC in the width direction, among the plurality of cells LC constituting one row (for example, RW1, RW2, RW3, RW4, RW5, or RW6), may be apart from each other with a certain separation distance therebetween.

In some example embodiments, in the plurality of cells LC constituting one row (for example, RW1, RW2, RW3, RW4, RW5, or RW6), two adjacent cells LC may perform the same function. In some example embodiments, the two adjacent cells LC may have the same structure. In some example embodiments, in the plurality of cells LC constituting one row (for example, RW1, RW2, RW3, RW4, RW5, or RW6), two adjacent cells LC may respectively perform different functions.

In some example embodiments, one cell LC selected from the plurality of cells LC, which are included in the cell block 12 of the integrated circuit device 10, and another cell LC adjacent to the selected cell LC in the height direction (the Y direction in FIG. 1) may have symmetric structures to each other about the cell interface portion CBC therebetween. For example, a reference logic cell LC_R in a third row RW3 and a lower logic cell LC_L in a second row RW2 may have symmetric structures to each other about the cell interface portion CBC therebetween. The reference logic cell LC_R in the third row RW3 and an upper logic cell LC_H in a fourth row RW4 may have symmetric structures to each other about the cell interface portion CBC therebetween. Although FIG. 1 illustrates the cell block 12 including six rows (for example, RW1, RW2, RW3, RW4, RW5, and RW6), this is only an example. The cell block 12 may include rows in various numbers selected as needed, and one row may include logic cells in various numbers selected as needed.

One selected from among a plurality of ground lines VSS and a plurality of power lines VDD may be arranged between a plurality of rows (for example, RW1, RW2, RW3, RW4, RW5, and RW6), which each include the plurality of cells LC arranged in a line in the width direction (the X direction in FIG. 1). The plurality of ground lines VSS and the plurality of power lines VDD may each extend in a first horizontal direction (the X direction) and may be alternately arranged apart from each other in a second horizontal direction (the Y direction). The second horizontal direction (the Y direction) is a direction that is orthogonal to the first horizontal direction (the X direction). Therefore, each of the plurality of ground lines VSS and the plurality of power lines VDD may be arranged to overlap the cell boundary CBD of the cell LC, the cell boundary CBD following the second horizontal direction (the Y direction).

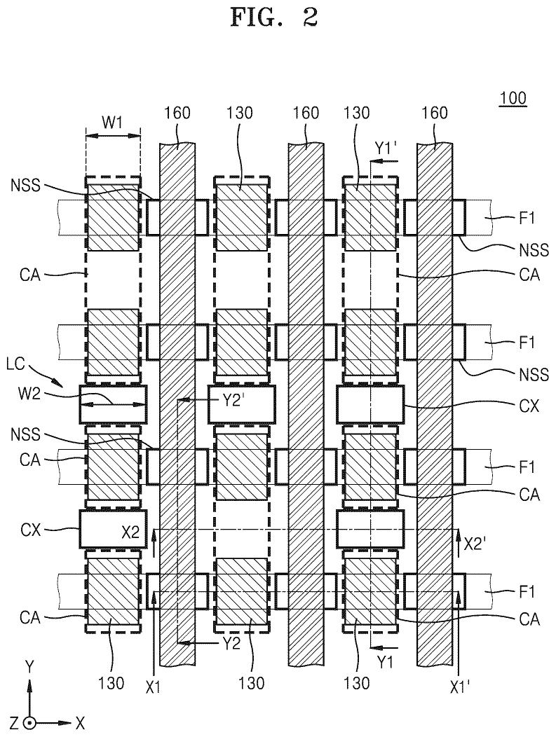

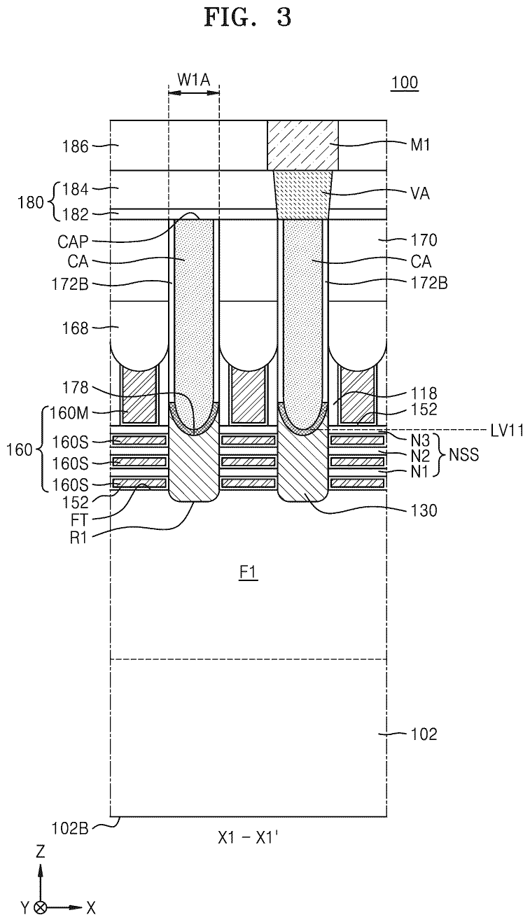

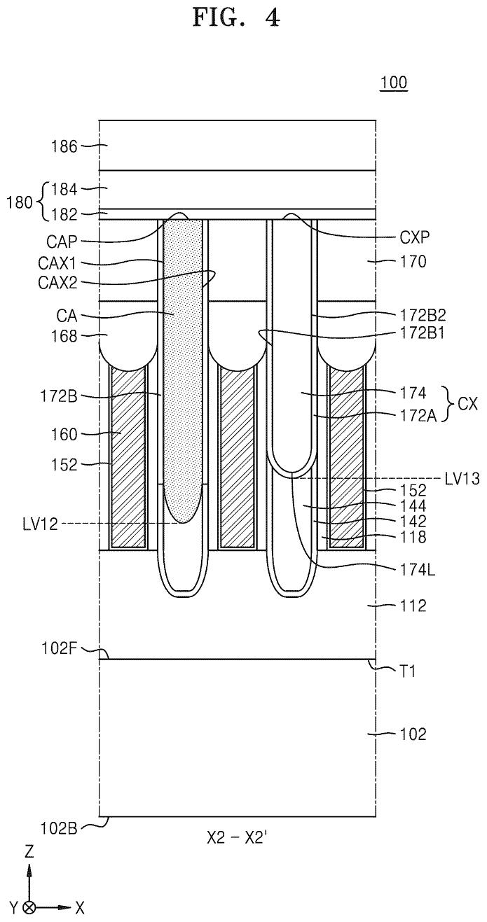

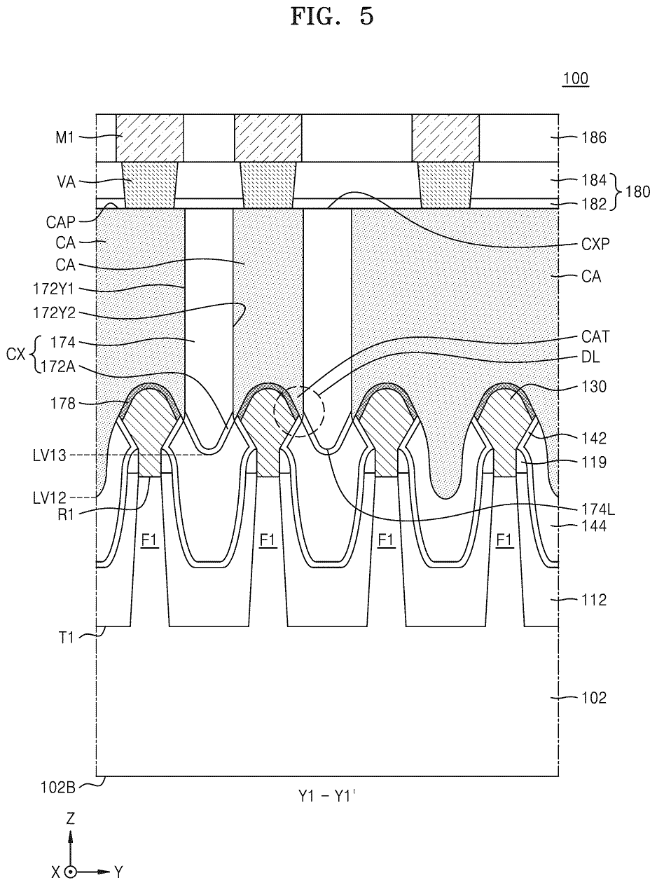

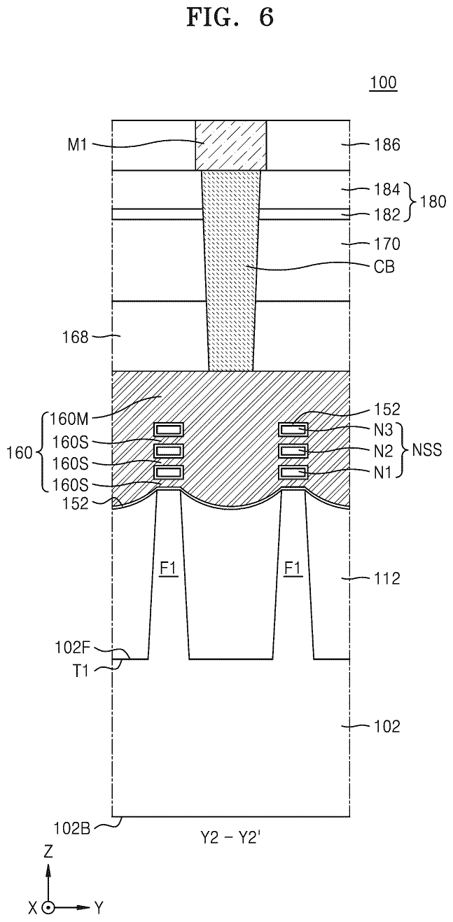

FIG. 2 is a planar layout diagram illustrating an integrated circuit device 100 according to some example embodiments. FIG. 3 is a cross-sectional view of the integrated circuit device 100, taken along a line X1-X1′ of FIG. 2. FIG. 4 is a cross-sectional view of the integrated circuit device 100, taken along a line X2-X2′ of FIG. 2. FIG. 5 is a cross-sectional view of the integrated circuit device 100, taken along a line Y1-Y1′ of FIG. 2. FIG. 6 is a cross-sectional view of the integrated circuit device 100, taken along a line Y2-Y2′ of FIG. 2. The integrated circuit device 100 including a field-effect transistor, which has a gate-all-around (GAA) structure including a nanowire or nanosheet-shaped active region and a gate surrounding the active region, is described with reference to FIGS. 2 to 6. The integrated circuit device 100 may constitute a portion of the plurality of cells LC shown in FIG. 1.

Referring to FIGS. 2 to 6, the integrated circuit device 100 may include a logic cell LC arranged on a substrate 102. The substrate 102 may have a frontside surface 102F and a backside surface 102B. A plurality of fin-type active regions F1 may be arranged on the substrate 102. The plurality of fin-type active regions F1 may protrude from the frontside surface 102F of the substrate 102 to define a plurality of trench regions T1 on the substrate 102. The plurality of fin-type active regions F1 may extend lengthwise in the first horizontal direction (the X direction) on the substrate 102 and may be arranged apart from each other in the second horizontal direction (the Y direction) that is perpendicular to the first horizontal direction (the X direction).

Each of the substrate 102 and the plurality of fin-type active regions F1 may include a semiconductor, such as Si or Ge, or a compound semiconductor, such as SiGe, SiC, GaAs, InAs, InGaAs, or InP. As used herein, each of the terms “SiGe”, “SiC”, “GaAs”, “InAs”, “InGaAs”, and “InP” refers to a material including elements contained in each term and is not a chemical formula representing a stoichiometric relationship. The substrate 102 may include a conductive region, for example, an impurity-doped well or an impurity-doped structure.

A device isolation film 112 may be arranged in the plurality of trench regions T1 on the substrate 102. The device isolation film 112 may be arranged in the plurality of trench regions T1 to cover a portion of a sidewall of each of the plurality of fin-type active regions F1. The device isolation film 112 may include, but is not limited to, a silicon oxide film.

A plurality of gate lines 160 may be arranged over the plurality of fin-type active regions F1 and the device isolation film 112. Each of the plurality of gate lines 160 may be arranged over the plurality of fin-type active regions F1 and may extend lengthwise in the second horizontal direction (the Y direction) across the plurality of fin-type active regions F1 to intersect the plurality of fin-type active regions F1.

As shown in FIGS. 3 and 6, in intersection areas between the plurality of fin-type active regions F1 and the plurality of gate lines 160, a plurality of nanosheet stacks NSS may be arranged over a fin top surface FT of each of the plurality of fin-type active regions F1. Each of the plurality of nanosheet stacks NSS may include at least one nanosheet arranged apart from the fin top surface FT of a fin-type active region F1 in the vertical direction (the Z direction) to face the fin top surface FT of the fin-type active region F1. As used herein, the term “nanosheet” refers to a conductive structure having a cross-section that is perpendicular or substantially perpendicular to a current-flowing direction. The nanosheet may be understood as including a nanowire.

Each of the plurality of nanosheet stacks NSS may include a first nanosheet N1, a second nanosheet N2, and a third nanosheet N3, which overlap each other in the vertical direction (the Z direction), over the fin-type active region F1. The first nanosheet N1, the second nanosheet N2, and the third nanosheet N3 may respectively have different vertical distances (Z-direction distances) from the fin top surface FT of the fin-type active region F1. Each of the plurality of gate lines 160 may surround the first nanosheet N1, the second nanosheet N2, and the third nanosheet N3, which overlap each other in the vertical direction (the Z direction).

FIG. 2 illustrates an example in which the planar shape of a nanosheet stack NSS is approximately quadrangular, but the inventive concepts are not limited thereto. The nanosheet stack NSS may have various planar shapes depending on respective planar shapes of the fin-type active region F1 and a gate line 160. In some example embodiments, the plurality of nanosheet stacks NSS and the plurality of gate lines 160 are arranged over one fin-type active region F1 and the plurality of nanosheet stacks NSS are arranged in a row in the first horizontal direction (the X direction) over the one fin-type active region F1. However, the respective numbers of nanosheet stacks NSS and gate lines 160, which are arranged over one fin-type active region F1, are not particularly limited.

Each of the first nanosheet N1, the second nanosheet N2, and the third nanosheet N3 of the nanosheet stack NSS may function as a channel region. In some example embodiments, each of the first nanosheet N1, the second nanosheet N2, and the third nanosheet N3 may have, but is not limited to, a thickness selected from a range of about 4 nm to about 6 nm. Here, the thickness of each of the first nanosheet N1, the second nanosheet N2, and the third nanosheet N3 refers to a size in the vertical direction (the Z direction). In some example embodiments, the first nanosheet N1, the second nanosheet N2, and the third nanosheet N3 may have the same or substantially the same thickness in the vertical direction (the Z direction). In some example embodiments, at least some of the first nanosheet N1, the second nanosheet N2, and the third nanosheet N3 may respectively have different thicknesses in the vertical direction (the Z direction). In some example embodiments, each of the first nanosheet N1, the second nanosheet N2, and the third nanosheet N3 of the nanosheet stack NSS may include a Si layer, a SiGe layer, or a combination thereof.

As shown in FIG. 3, the first nanosheet N1, the second nanosheet N2, and the third nanosheet N3, which are included in one nanosheet stack NSS, may have equal or similar sizes to each other in the first horizontal direction (the X direction). In some example embodiments, unlike the example shown in FIG. 3, at least some of the first nanosheet N1, the second nanosheet N2, and the third nanosheet N3, which are included in one nanosheet stack NSS, may respectively have different sizes in the first horizontal direction (the X direction). In some example embodiments, each of the plurality of nanosheet stacks NSS includes three nanosheets, but the inventive concepts are not limited thereto. For example, the nanosheet stack NSS may include at least one nanosheet, and the number of nanosheets constituting the nanosheet stack NSS is not particularly limited.

As shown in FIGS. 3 and 6, each of the plurality of gate lines 160 may include a main gate portion 160M and a plurality of sub-gate portions 160S. The main gate portion 160M may extend lengthwise in the second horizontal direction (the Y direction) to cover an upper surface of the nanosheet stack NSS. The plurality of sub-gate portions 160S may be integrally connected to the main gate portion 160M and may be respectively arranged one-by-one between the first nanosheet N1, the second nanosheet N2, and the third nanosheet N3 and between the first nanosheet N1 and the fin top surface FT of the fin-type active region F1. In the vertical direction (the Z direction), the thickness of each of the plurality of sub-gate portions 160S may be less than the thickness of the main gate portion 160M.

As shown in FIGS. 3 and 5, a plurality of recesses R1 may be formed in the fin-type active region F1. A vertical level of the lowermost surface of each of the plurality of recesses R1 may be lower than a vertical level of the fin top surface FT of the fin-type active region F1. As used herein, the term “vertical level” refers to a distance in the vertical direction (the Z direction or a-Z direction) from the frontside surface 102F of the substrate 102. A plurality of source/drain regions 130 may be respectively arranged in the plurality of recesses R1. Each of the plurality of source/drain regions 130 may be arranged adjacent to at least one gate line 160 selected from the plurality of gate lines 160.

The plurality of source/drain regions 130 may be respectively arranged one-by-one on the plurality of fin-type active regions F1 between a pair of gate lines 160 that are selected from the plurality of gate lines 160 and adjacent to each other. The plurality of source/drain regions 130 arranged between the pair of gate lines 160 may be aligned in a row on an imaginary straight line (which may be referred to as a first straight line, herein) that follows the second horizontal direction (the Y direction).

Each of the plurality of source/drain regions 130 may have surfaces facing the first nanosheet N1, the second nanosheet N2, and the third nanosheet N3, which are included in the nanosheet stack NSS adjacent thereto. Each of the plurality of source/drain regions 130 may be in contact with the first nanosheet N1, the second nanosheet N2, and the third nanosheet N3, which are included in the nanosheet stack NSS adjacent thereto.

Each of the plurality of source/drain regions 130 may include an epitaxially grown semiconductor layer. In some example embodiments, each of the plurality of source/drain regions 130 may include an epitaxially grown Si layer, an epitaxially grown SiC layer, an embedded SiGe structure including a plurality of SiGe layers that are epitaxially grown, or the like.

In some example embodiments, when a source/drain region 130 constitutes an NMOS transistor, the source/drain region 130 may include a SiC layer doped with an n-type dopant. The n-type dopant may be selected from phosphorus (P), arsenic (As), and antimony (Sb).

In some example embodiments, when the source/drain region 130 constitutes a PMOS transistor, the source/drain region 130 may include a SiGe layer doped with a p-type dopant. The p-type dopant may be selected from boron (B) and gallium (Ga). When the source/drain region 130 constitutes a PMOS transistor, the source/drain region 130 may include a blocking layer, which forms the outermost surface of the source/drain region 130, and a main body layer surrounded by the blocking layer. The blocking layer and the main body layer may be integrally connected to each other. The blocking layer and the main body layer may include SiGe layers respectively having different Ge content ratios, and the Ge content ratio in the blocking layer may be less than the Ge content ratio in the main body layer. In some example embodiments, when the source/drain region 130 constitutes a PMOS transistor, the source/drain region 130 may include a blocking layer, a buffer layer, and a main body layer, which are sequentially arranged in the stated order in the vertical direction (the Z direction) from a lower surface of a recess R1 and continuously form one body. The blocking layer, the buffer layer, and the main body layer may each include a Si₁₋ₓGeₓ layer (where x>0) doped with a p-type dopant and may respectively have different Ge content ratios. In some example embodiments, each of the blocking layer, the buffer layer, and the main body layer may include a Si₁₋ₓGeₓ layer (where x>0) doped with a p-type dopant, and the Ge content ratio in the buffer layer may be greater than the Ge content ratio in the blocking layer and less than the Ge content ratio in the main body layer. For example, each of the blocking layer, the buffer layer, and the main body layer may include a Si₁₋ₓGeₓ layer (where x>0) doped with boron (B), and the blocking layer, the buffer layer, and the main body layer may respectively have increasing Ge content ratios with the increasing distance from the fin-type active region F1. For example, the blocking layer may include a Si₁₋ₓGeₓ layer (where 0.05≤x≤0.07) doped with boron (B), the buffer layer may include a Si₁₋ₓGeₓ layer (where 0.40≤x≤0.45) doped with boron (B), and the main body layer may include a Si₁₋ₓGeₓ layer (where 0.45<x≤0.70) doped with boron (B). For example, the Ge content ratio in the blocking layer may be about 5 at % to about 7 at %, the Ge content ratio in the buffer layer may be about 40 at % to about 45 at %, and the Ge content ratio in the main body layer may be greater than about 45 at % but not more than about 70 at %, but the inventive concepts are not limited thereto.

Each of the plurality of gate lines 160 may include a metal, a metal nitride, a metal carbide, or a combination thereof. The metal may be selected from Ti, W, Ru, Nb, Mo, Hf, Ni, Co, Pt, Yb, Tb, Dy, Er, and Pd. The metal nitride may be selected from TiN and TaN. The metal carbide may include TiAlC. However, a material constituting each of the plurality of gate lines 160 is not limited to the examples set forth above.

A gate dielectric film 152 may be arranged between the nanosheet stack NSS and the gate line 160. In some example embodiments, the gate dielectric film 152 may include a stack structure of an interface dielectric film and a high-k film. The interface dielectric film may include a low-k material film having a dielectric constant of about 9 or less, for example, a silicon oxide film, a silicon oxynitride film, or a combination thereof. In some example embodiments, the interface dielectric film may be omitted. The high-k film may include a material having a dielectric constant that is greater than that of a silicon oxide film. For example, the high-k film may have a dielectric constant of about 10 to about 25. The high-k film may include, but is not limited to, hafnium oxide.

Either sidewall of each of the plurality of sub-gate portions 160S, which are included in each of the plurality of gate lines 160, may be apart from the source/drain region 130 with the gate dielectric film 152 therebetween. The gate dielectric film 152 may be arranged between a sub-gate portion 160S of the gate line 160 and each of the first nanosheet N1, the second nanosheet N2, and the third nanosheet N3 and between the sub-gate portion 160S of the gate line 160 and the source/drain region 130.

The plurality of nanosheet stacks NSS may be respectively arranged over fin top surfaces FT of the plurality of fin-type active regions F1 in the intersection areas between the plurality of fin-type active regions F1 and the plurality of gate lines 160 and may each be apart from the fin-type active region F1 to face the fin top surface FT of the fin-type active region F1. A plurality of nanosheet transistors may be respectively formed on the substrate 102 in the intersection areas between the plurality of fin-type active regions F1 and the plurality of gate lines 160. Each of the plurality of nanosheet transistors may include an NMOS transistor, a PMOS transistor, or a combination thereof.

As shown in FIGS. 3 and 4, both sidewalls of the gate line 160 may be respectively covered by a plurality of main insulating spacers 118. Each of the plurality of main insulating spacers 118 may be arranged on the upper surface of the nanosheet stack NSS to cover a sidewall of the main gate portion 160M. Each of the plurality of main insulating spacers 118 may be apart from the gate line 160 with the gate dielectric film 152 therebetween.

As shown in FIG. 5, a plurality of side insulating spacers 119 may be arranged on the device isolation film 112. At least a portion of each of the plurality of side insulating spacers 119 may cover a sidewall of the source/drain region 130. In some example embodiments, each of the plurality of side insulating spacers 119 may be integrally connected to the main insulating spacer 118 adjacent thereto.

Each of the plurality of main insulating spacers 118 and the plurality of side insulating spacers 119 may include silicon nitride, silicon oxide, SiOC, SiOCN, SiCN, SiBN, SiON, SiBCN, SiOF, SiOCH, or a combination thereof. Each of the plurality of main insulating spacers 118 and the plurality of side insulating spacers 119 may include a single film including a film of a material selected from the materials listed above or may include a multi-film including a plurality of films of materials selected from the materials listed above. As used herein, each of the terms “SiOC”, “SiOCN”, “SiCN”, “SiBN”, “SiON”, “SiBCN”, “SiOF”, and “SiOCH” refers to a material including elements contained in each term and is not a chemical formula representing a stoichiometric relationship.

As shown in FIGS. 3, 4, and 6, an upper surface of each of the plurality of gate lines 160, an upper surface of each of a plurality of gate dielectric films 152, and an upper surface of each of the plurality of main insulating spacers 118 may be covered by each of a plurality of capping insulating patterns 168. Each of the plurality of capping insulating patterns 168 may include a silicon nitride film. The plurality of capping insulating patterns 168 may be covered by a first upper insulating film 170. The first upper insulating film 170 may include an oxide film, a nitride film, an ultra-low k (ULK) film having an ultra-low dielectric constant (that is, k) of about 2.2 to about 2.4, or a combination thereof. For example, the first upper insulating film 170 may include, but is not limited to, a tetraethylorthosilicate (TEOS) film, a high-density plasma (HDP) oxide film, a boro-phospho-silicate glass (BPSG) film, a flowable chemical vapor deposition (FCVD) oxide film, a SiON film, a SiN film, a SiOC film, a SiCOH film, or a combination thereof.

The plurality of source/drain regions 130, the device isolation film 112, the plurality of main insulating spacers 118, the plurality of side insulating spacers 119, the plurality of capping insulating patterns 168, and the first upper insulating film 170, on or over the substrate 102, may each include a portion covered by an insulating liner 142. An inter-gate dielectric 144 may be arranged on the insulating liner 142. In some example embodiments, the insulating liner 142 may include, but is not limited to, silicon nitride, SiCN, SiBN, SiON, SiOCN, SiBCN, or a combination thereof. The inter-gate dielectric 144 may include, but is not limited to, a silicon oxide film. Herein, the insulating liner 142 and the inter-gate dielectric 144 may be collectively referred to as an insulating structure.

As shown in FIGS. 3, 4, and 5, a plurality of source/drain contacts CA may be respectively arranged on the plurality of source/drain regions 130. Each of the plurality of source/drain contacts CA may be configured to be electrically connected to at least one source/drain region 130 selected from the plurality of source/drain regions 130. For example, one source/drain contact CA may be connected to one source/drain region 130 or two source/drain regions 130, but the inventive concepts are not limited thereto.

The plurality of source/drain contacts CA may be aligned in a row on an imaginary straight line (which may be referred to as a first straight line, herein), which follows the second horizontal direction (the Y direction), between a pair of gate lines 160 that are selected from the plurality of gate lines 160 and adjacent to each other. The plurality of source/drain contacts CA between two adjacent gate lines 160 from among the plurality of gate lines 160 may be arranged in a row in the second horizontal direction (the Y direction) to be apart from each other in the second horizontal direction (the Y direction).

As shown in FIG. 2, at least one contact isolation insulating structure CX may be arranged between each of the plurality of gate lines 160. The contact isolation insulating structure CX may be arranged between two source/drain contacts CA adjacent to each other in the second horizontal direction (the Y direction) to electrically isolate the two source/drain contacts CA from each other. A plurality of contact isolation insulating structures CX between a pair of gate lines 160 adjacent to each other from among the plurality of gate lines 160 may each be arranged one-by-one between a pair of source/drain contacts CA adjacent to each other in the second horizontal direction (the Y direction) from among the plurality of source/drain contacts CA and may be aligned in a row on an imaginary straight line (for example, the first straight line) that follows the second horizontal direction (the Y direction).

The plurality of source/drain contacts CA and the plurality of contact isolation insulating structures CX may pass through the first upper insulating film 170 in the vertical direction (the Z direction) between a pair of gate lines 160 adjacent to each other from among the plurality of gate lines 160.

As shown in FIGS. 4 and 5, each of the plurality of contact isolation insulating structures CX may include a contact isolation insulating pattern 174 and a first isolation insulating liner 172A surrounding a portion of the contact isolation insulating pattern 174. A lower surface 174L of each of a plurality of contact isolation insulating patterns 174 and sidewalls 172B1 and 172B2 of each of the plurality of contact isolation insulating patterns 174 in the first horizontal direction (the X direction) may each be covered by the first isolation insulating liner 172A. The lower surface 174L of the contact isolation insulating pattern 174 and the sidewalls 172B1 and 172B2 thereof in the first horizontal direction (the X direction) may each be in contact with the first isolation insulating liner 172A. Sidewalls 172Y1 and 172Y2 of each of the plurality of contact isolation insulating patterns 174 in the second horizontal direction (the X direction) may each be in contact with a single source/drain contact CA that is selected from the plurality of source/drain contacts CA and adjacent thereto.

Sidewalls CAX1 and CAX2 (which may be referred to as first sidewalls, herein) of each of the plurality of source/drain contacts CA in the first horizontal direction (the X direction) may be covered by a second isolation insulating liner 172B. The sidewalls CAX1 and CAX2 of each of the plurality of source/drain contacts CA in the first horizontal direction (the X direction) may be in contact with the second isolation insulating liner 172B. Sidewalls of each of the plurality of source/drain contacts CA in the second horizontal direction (the Y direction) may not be covered by the second isolation insulating liner 172B. The sidewalls of each of the plurality of source/drain contacts CA in the second horizontal direction (the Y direction) may each be in contact with the sidewall 172Y1 or 172Y2, in the second horizontal direction (the Y direction), of the contact isolation insulating pattern 174 adjacent thereto.

The first isolation insulating liner 172A of each of the plurality of contact isolation insulating structures CX and each of a plurality of second isolation insulating liners 172B respectively covering the plurality of source/drain contacts CA may include the same constituent material. In some example embodiments, each of the first isolation insulating liner 172A and the second isolation insulating liner 172B may include silicon nitride, silicon oxide, SiOC, SiOCN, SiCN, SiBN, SiON, SiBCN, SiOF, SiOCH, or a combination thereof.

As shown in FIG. 2, in the first horizontal direction (the X direction), a width W1 of each of the plurality of source/drain contacts CA may be less than a width W2 of each of the plurality of contact isolation insulating structures CX. A width W1A (see FIG. 3), in the first horizontal direction (the X direction), of a structure including one source/drain contact CA (which may be referred to as a first source/drain contact, herein), which is selected from the plurality of source/drain contacts CA, and one second isolation insulating liner 172B, which is selected from the plurality of second isolation insulating liners 172B and covers the sidewalls CAX1 and CAX2 (which may be referred to as first sidewalls, herein) of the selected one source/drain contact CA in the first horizontal direction (the X direction), may be equal or similar to the width W2, in the first horizontal direction (the X direction), of one contact isolation insulating structure CX selected from the plurality of contact isolation insulating structures CX.

As shown in FIGS. 4 and 5, the uppermost surface CXP of each of the plurality of contact isolation insulating structures CX may be coplanar with the upper surface CAP of each of the plurality of source/drain contacts CA. At least one contact isolation insulating structure CX selected from the plurality of contact isolation insulating structures CX may include a portion located to overlap the device isolation film 112 in the vertical direction (the Z direction) and contacting the inter-gate dielectric 144 that is a portion of the insulating structure. The at least one contact isolation insulating structure CX may be apart from the device isolation film 112 in the vertical direction (the Z direction) with the insulating liner 142 and the inter-gate dielectric 144 therebetween. The first isolation insulating liner 172A of each of the at least one contact isolation insulating structure CX may be in contact with the inter-gate dielectric 144 and may be apart from the insulating liner 142 and the device isolation film 112 with the inter-gate dielectric 144 therebetween. The contact isolation insulating pattern 174 of each of the at least one contact isolation insulating structure CX may be apart from each of the inter-gate dielectric 144, the insulating liner 142, and the device isolation film 112 with the first isolation insulating liner 172A therebetween.

In each of the plurality of contact isolation insulating structures CX, a portion overlapping the device isolation film 112 in the vertical direction (the Z direction) may have a surface that faces the inter-gate dielectric 144 and the insulating liner 142 and is convex toward the device isolation film 112. A portion of each of the first isolation insulating liner 172A and the contact isolation insulating pattern 174 of the contact isolation insulating structure CX may have a surface that faces the inter-gate dielectric 144 and the insulating liner 142 and is convex toward the device isolation film 112.

At least one source/drain contact CA selected from the plurality of source/drain contacts CA may each include a portion located to overlap the device isolation film 112 in the vertical direction (the Z direction) and contacting the inter-gate dielectric 144. The portion, contacting the inter-gate dielectric 144, of the source/drain contact CA may have a surface that is convex toward the device isolation film 112. The at least one source/drain contact CA may be apart from the device isolation film 112 in the vertical direction (the Z direction) with the insulating liner 142 and the inter-gate dielectric 144 therebetween.

As shown in FIG. 4, in a cross-sectional view of the source/drain contact CA, taken in the first horizontal direction (the X direction), a portion of the source/drain contact CA, which overlaps the device isolation film 112 in the vertical direction (the Z direction), may include a lower portion that is closer to the device isolation film 112 than the second isolation insulating liner 172B. The lower portion of the source/drain contact CA over the device isolation film 112 may be in contact with the inter-gate dielectric 144. In each of the plurality of source/drain contacts CA, a vertical level LV12 (see FIG. 4) of the lowermost surface of a portion overlapping the device isolation film 112 in the vertical direction (the Z direction) may be closer to the device isolation film 112 than a vertical level LV11 (see FIG. 3) of the lowermost surface of a portion arranged over the source/drain region 130 to overlap the fin-type active region F1 in the vertical direction (the Z direction). In each of the plurality of source/drain contacts CA, the length, in the vertical direction (the Z direction), of the portion overlapping the device isolation film 112 in the vertical direction (the Z direction) may be greater than the length, in the vertical direction (the Z direction), of the portion arranged over the source/drain region 130 to overlap the fin-type active region F1 in the vertical direction (the Z direction).

The vertical level LV12 (see FIGS. 4 and 5) of the lowermost surface of the portion overlapping the device isolation film 112 in the vertical direction (the Z direction), in each of the plurality of source/drain contacts CA, may be closer to the device isolation film 112 than a vertical level LV13 (see FIGS. 4 and 5) of the lowermost surface of the portion overlapping the device isolation film 112 in the vertical direction (the Z direction), in each of the plurality of contact isolation insulating structures CX. The length, in the vertical direction (the Z direction), of the portion overlapping the device isolation film 112 in the vertical direction (the Z direction), in each of the plurality of source/drain contacts CA, may be greater than the length, in the vertical direction (the Z direction), of the portion overlapping the device isolation film 112 in the vertical direction (the Z direction), in each of the plurality of contact isolation insulating structures CX.

A metal silicide film 178 may be arranged between the source/drain region 130 and the source/drain contact CA that are connected to each other. The metal silicide film 178 may include a metal including Ti, W, Ru, Nb, Mo, Hf, Ni, Co, Pt, Yb, Tb, Dy, Er, or Pd. For example, the metal silicide film 178 may include, but is not limited to, titanium silicide.

Each of the plurality of source/drain contacts CA may be arranged over the fin-type active region F1 to pass through the first upper insulating film 170, the inter-gate dielectric 144, and the insulating liner 142 in the vertical direction (the Z direction) and may be connected to the source/drain region 130 via the metal silicide film 178. As shown in FIG. 3, in a cross-sectional view taken in the first horizontal direction (the X direction), a lower surface, facing the source/drain region 130, of each of the plurality of source/drain contacts CA may include a convex surface toward the source/drain region 130, and at least some of the plurality of source/drain regions 130 may each have a concave surface facing the convex surface of the source/drain contact CA. As shown in FIG. 5, in a cross-sectional view taken in the second horizontal direction (the Y direction), the lower surface, facing the source/drain region 130, of each of the plurality of source/drain contacts CA may include a concave surface toward the source/drain region 130, and at least some of the plurality of source/drain regions 130 may each have a convex surface facing the concave surface of the source/drain contact CA.

As shown in FIGS. 3 and 4, each of the plurality of source/drain contacts CA may be apart from, in the first horizontal direction (the X direction), the main gate portion 160M of the gate line 160 adjacent thereto with the main insulating spacer 118 therebetween.

As indicated by a dashed circle DL in FIG. 5, among the plurality of source/drain contacts CA, at least one source/drain contact CA may include a contact tail CAT adjacent to an edge portion of the source/drain region 130. The contact tail CAT of the source/drain contact CA may include a portion that is arranged between one selected from the plurality of source/drain regions 130 and one selected from the plurality of contact isolation insulating structures CX and locally extends in the vertical direction (the Z direction) toward the device isolation film 112 and the substrate 102 along the surface of the selected one contact isolation insulating structure CX. The contact tail CAT may have a wedge shape that is acuate toward the device isolation film 112. The metal silicide film 178 may include a portion between the contact tail CAT of the source/drain contact CA and the source/drain region 130. The contact tail CAT of the source/drain contact CA may be arranged between the contact isolation insulating structure CX adjacent thereto and the source/drain region 130 adjacent thereto. A relatively narrow gap space, which is arranged between and defined by the contact isolation insulating structure CX and the source/drain region 130 that are adjacent to each other, may be filled with only the contact tail CAT of the source/drain contact CA and the metal silicide film 178 contacting the contact tail CAT, and no other insulating film or no other insulating pattern may be arranged in the gap space. Because the source/drain contact CA includes the contact tail CAT, the contact area between the source/drain contact CA and the source/drain region 130 may be relatively increased, and thus, the contact resistance between the source/drain contact CA and the source/drain region 130 may be relatively reduced.

In the integrated circuit device 100, any other insulating film around the source/drain region 130 may not be arranged between the source/drain contact CA and the contact isolation insulating structure CX. For example, none of the insulating liner 142 and the inter-gate dielectric 144 may include a portion between the source/drain contact CA and the contact isolation insulating structure CX.

As shown in FIG. 5, a pair of source/drain contacts CA adjacent to each other in the second horizontal direction (the Y direction), among the plurality of source/drain contacts CA, may be respectively in contact with both sidewalls of one contact isolation insulating structure CX arranged between the pair of source/drain contacts CA, and the pair of source/drain contacts CA adjacent to each other may have asymmetric structures to each other about the one contact isolation insulating structure CX. In some example embodiments, each of the plurality of source/drain contacts CA may include only a metal plug including a single metal. In some example embodiments, each of the plurality of source/drain contacts CA may include a metal plug and a conductive barrier film surrounding the metal plug. The metal plug may include, but is not limited to, molybdenum (Mo), tungsten (W), cobalt (Co), ruthenium (Ru), manganese (Mn), titanium (Ti), tantalum (Ta), aluminum (Al), copper (Cu), a combination thereof, or an alloy thereof. The conductive barrier film may include a metal or a conductive metal nitride. For example, the conductive barrier film may include, but is not limited to, Ti, Ta, W, TiN, TaN, WN, WCN, TiSiN, TaSiN, WSiN, or a combination thereof.

In some example embodiments, in each of the plurality of contact isolation insulating structures CX, the contact isolation insulating pattern 174 may include silicon nitride, silicon oxide, SiOC, SiOCN, SiCN, SiBN, SiON, SiBCN, SiOF, SiOCH, or a combination thereof. In some example embodiments, in each of the plurality of contact isolation insulating structures CX, the first isolation insulating liner 172A and the contact isolation insulating pattern 174 may respectively include different insulating materials. In some example embodiments, in each of the plurality of contact isolation insulating structures CX, the first isolation insulating liner 172A and the contact isolation insulating pattern 174 may include the same insulating material. In some example embodiments, the first isolation insulating liner 172A and the contact isolation insulating pattern 174 may respectively include films formed by different deposition methods. For example, the first isolation insulating liner 172A may include a film formed by an atomic layer deposition (ALD) process, and the contact isolation insulating pattern 174 may include a film formed by a chemical vapor deposition (CVD) process. In some example embodiments, the contact isolation insulating pattern 174 of each of the plurality of contact isolation insulating structures CX may include an air gap. As used herein, the term “air gap” may refer to a space including the atmosphere or including other gases that may be present during a fabrication process.

As shown in FIGS. 3 to 6, the upper surface of each of the plurality of source/drain contacts CA, the plurality of contact isolation insulating structures CX, and the first upper insulating film 170 may be covered by an upper insulating structure 180. The upper insulating structure 180 may include an etch stop film 182 and a second upper insulating film 184, which are stacked in the stated order on each of the plurality of source/drain contacts CA, the plurality of contact isolation insulating films CX, and the first upper insulating film 170. The etch stop film 182 may include silicon carbide (SiC), SiN, nitrogen-doped silicon carbide (SiC:N), SiOC, AlN, AlON, AlO, AlOC, or a combination thereof. A constituent material of the second upper insulating film 184 is the same as the constituent material of the first upper insulating film 170 described above.

As shown in FIGS. 3 and 5, a plurality of source/drain via contacts VA may be respectively arranged on the plurality of source/drain contacts CA. Each of the plurality of source/drain via contacts VA may pass through the upper insulating structure 180 to contact the source/drain contact CA. Each of the plurality of source/drain regions 130 may be configured to be electrically connected to a source/drain via contact VA through the source/drain contact CA. A lower surface of each of the plurality of source/drain via contacts VA may be in contact with the upper surface of the source/drain contact CA.

As shown in FIG. 6, a gate contact CB may be arranged on the gate line 160. The gate contact CB may be configured to pass through the upper insulating structure 180, the first upper insulating film 170, and the capping insulating pattern 168 in the vertical direction (the Z direction) to be connected to the gate line 160. A lower surface of the gate contact CB may be in contact with an upper surface of the gate line 160.

The plurality of source/drain via contacts VA and the gate contact CB may each include a contact plug including at least one selected from molybdenum (Mo), tungsten (W), cobalt (Co), ruthenium (Ru), manganese (Mn), titanium (Ti), tantalum (Ta), aluminum (Al), copper (Cu), a combination thereof, and an alloy thereof. However, a constituent material of the contact plug is not limited to the examples set forth above. In some example embodiments, the plurality of source/drain via contacts VA and the gate contact CB may each further include a conductive barrier pattern surrounding a portion of the contact plug. The conductive barrier pattern, which is included in each of the plurality of source/drain via contacts VA and the gate contact CB, may include a metal or a metal nitride. For example, the conductive barrier pattern may include, but is not limited to, Ti, Ta, W, TiN, TaN, WN, WCN, TiSiN, TaSiN, WSiN, or a combination thereof.

The upper surface of each of the upper insulating structure 180, the plurality of source/drain via contacts VA, and the gate contact CB may be covered by an interlayer dielectric 186. A constituent material of the interlayer dielectric 186 is the same as the constituent material of the first upper insulating film 170 described above.

A plurality of upper wiring layers M1 may be arranged through the interlayer dielectric 186. Each of the plurality of upper wiring layers M1 may be connected to a source/drain via contact VA, which is selected from the plurality of source/drain via contacts VA thereunder, or to the gate contact CB thereunder. Each of the plurality of upper wiring layers M1 may include, but is not limited to, molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof.

A frontside wiring structure (not shown) may be arranged on the plurality of upper wiring layers M1 and the interlayer dielectric 186. The frontside wiring structure may include a plurality of wiring layers, a plurality of via contacts, and an interlayer dielectric covering the plurality of wiring layers and the plurality of via contacts.

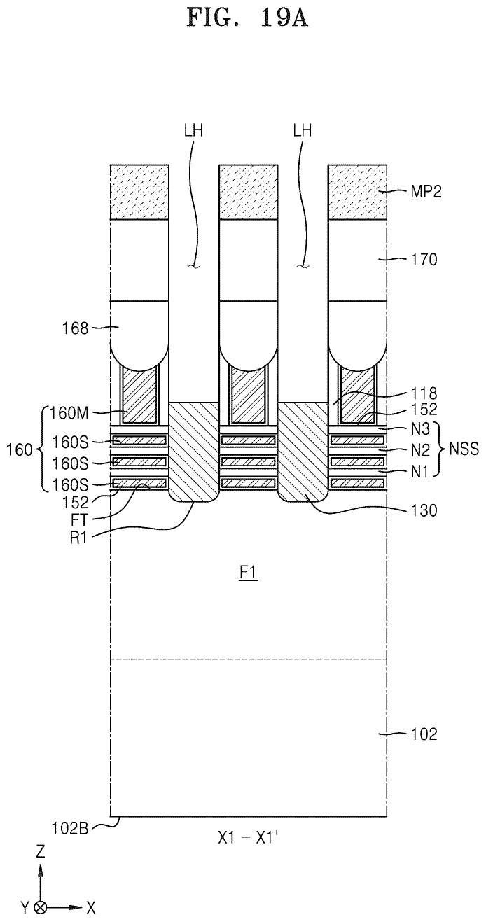

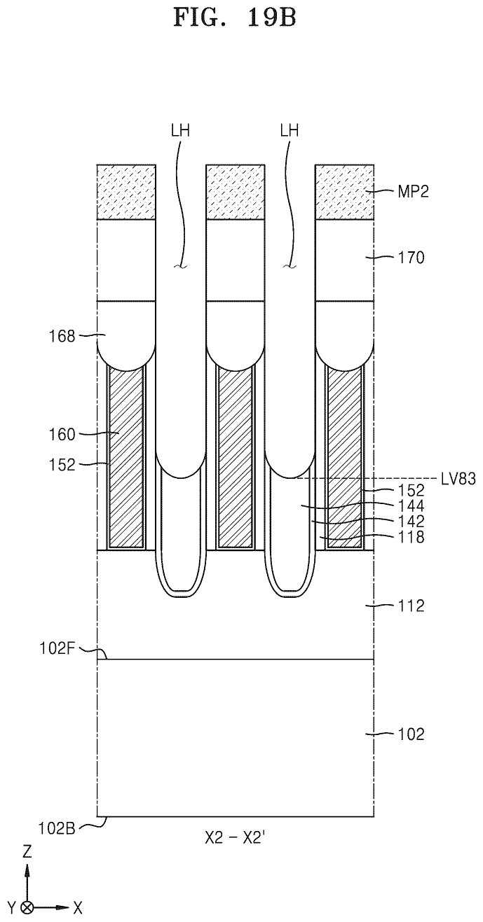

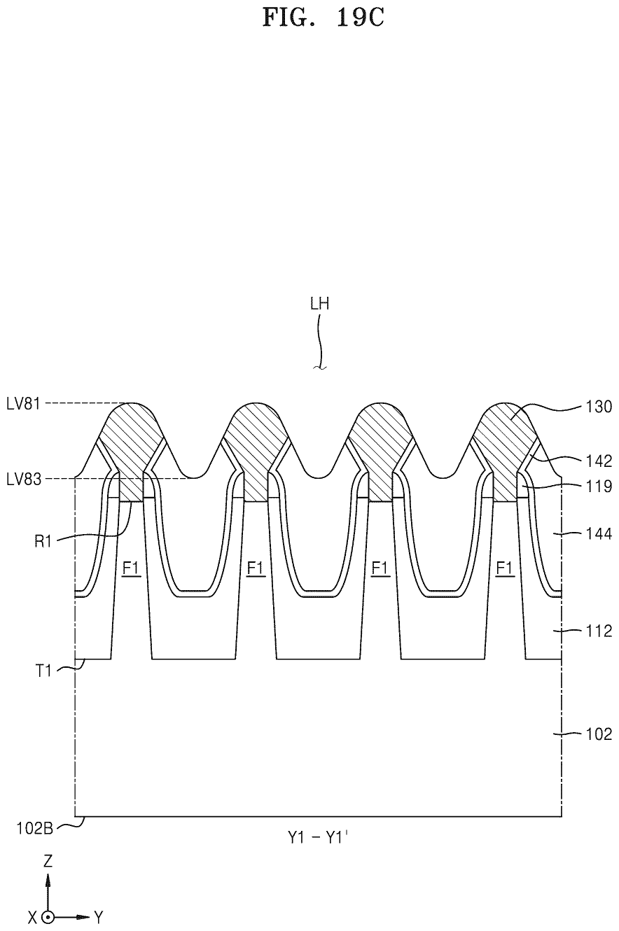

As described with reference to FIGS. 2 to 6, the integrated circuit device 100 includes the plurality of source/drain contacts CA, which are respectively connected to the plurality of source/drain regions 130, and the plurality of contact isolation insulating structures CX, which are arranged one-by-one between each of the plurality of source/drain contacts CA. The plurality of source/drain contacts CA and the plurality of contact isolation insulating structures CX may be aligned in a row on a straight line, which follows the second horizontal direction (the Y direction), between a pair of gate lines 160 adjacent to each other. In the integrated circuit device 100, the plurality of source/drain contacts CA and the plurality of contact isolation insulating structures CX, which are aligned in a row on a straight line following the second horizontal direction (the Y direction), may be formed by forming a line-shaped space (for example, a line-shaped space LH shown in FIGS. 19B and 19C), which extends lengthwise in the second horizontal direction (the Y direction), in advance and then filling the line-shaped space with the plurality of source/drain contacts CA and the plurality of contact isolation insulating structures CX. According to the inventive concepts, after the line-shaped space is formed, the plurality of source/drain contacts CA and the plurality of contact isolation insulating structures CX are formed in the line-shaped space, whereby a relatively large contact area between the source/drain region 130 and the source/drain contact CA may be secured, as compared with a general process, for example, a process of forming a plurality of relatively narrow and deep holes for forming the plurality of source/drain contacts CA and then forming a plurality of source/drain contacts to be arranged one-by-one in each of the plurality of holes. Therefore, the contact resistance between the source/drain contact CA and the source/drain region 130 may be relatively reduced, and thus, even when the integrated circuit device 100 has a device area reduced due to down-scaling, the reliability of the integrated circuit device 100 may improve.

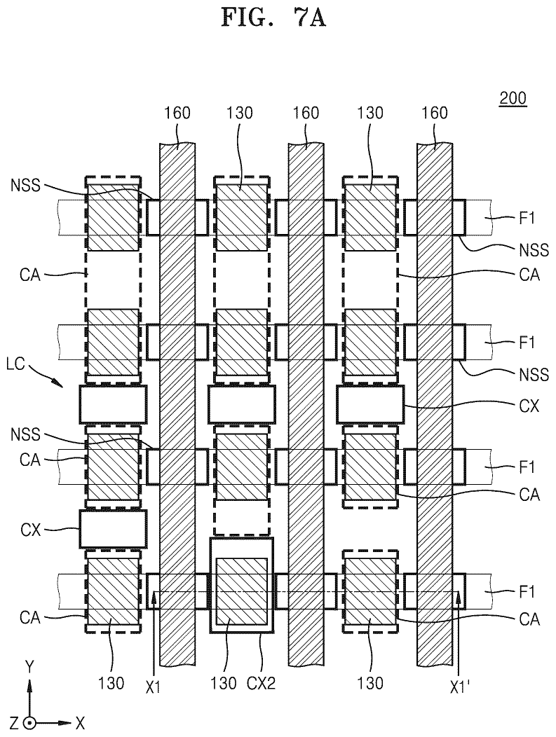

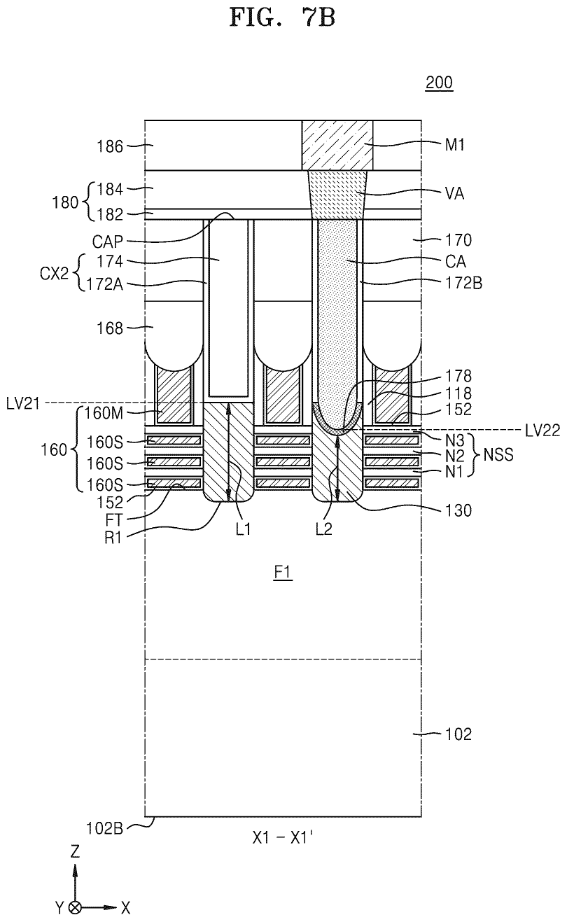

FIG. 7A is a planar layout diagram illustrating an integrated circuit device 200 according to some example embodiments. FIG. 7B is a cross-sectional view of the integrated circuit device 200, taken along a line X1-X1′ of FIG. 7A. In FIGS. 7A and 7B, the same reference numerals as in FIGS. 2 to 6 respectively denote the same members, and here, repeated descriptions thereof are omitted. Components shown in FIGS. 7A and 7B may constitute a portion of the plurality of cells LC shown in FIG. 1.

Referring to FIGS. 7A and 7B, the integrated circuit device 200 has substantially the same configuration as the integrated circuit device 100 described with reference to FIGS. 2 to 6. However, the integrated circuit device 200 may include a contact isolation insulating structure CX2 arranged to overlap, in the vertical direction (the Z direction), the source/drain region 130 on the fin-type active region F1. Herein, the contact isolation insulating structure CX2 may be referred to as a second contact isolation insulating structure.

The contact isolation insulating structure CX2 may have the same or substantially the same configuration as the contact isolation insulating structure CX described with reference to FIGS. 2, 4, and 5. The contact isolation insulating structure CX2 may include a first isolation insulating liner 172A and a contact isolation insulating pattern 174. Detailed configurations of the first isolation insulating liner 172A and the contact isolation insulating pattern 174 are the same as those described with reference to FIGS. 2, 4, and 5.

A vertical level LV21 of the lowermost surface of a portion, which is arranged on the source/drain region 130, of the contact isolation insulating structure CX2 overlapping the fin-type active region F1 in the vertical direction (the Z direction) may be farther from the fin-type active region F1 than a vertical level LV22 of the lowermost surface of a portion, which is arranged on the source/drain region 130, of the source/drain contact CA overlapping the fin-type active region F1 in the vertical direction (the Z direction). Therefore, a first length L1, in the vertical direction (the Z direction), of the source/drain region 130 arranged on the fin-type active region F1 to overlap the contact isolation insulating structure CX2 may be greater than a second length L2, in the vertical direction (the Z direction), of the source/drain region 130 arranged on the fin-type active region F1 to overlap the source/drain contact CA. Therefore, because the source/drain region 130 overlapping the contact isolation insulating structure CX2, among the plurality of source/drain regions 130, has a relatively large volume, the source/drain region 130 may induce sufficient strain to increase carrier mobility, according to the channel type of a transistor, in the channel region of each of the first nanosheet N1, the second nanosheet N2, and the third nanosheet N3 of the nanosheet stack NSS adjacent to the source/drain region 130.

A separation distance in the vertical direction (the Z direction) between the contact isolation insulating structure CX2 and the fin-type active region F1, which are apart from each other with one source/drain region 130 on the fin-type active region F1 therebetween, may be greater than a separation distance in the vertical direction (the Z direction) between the source/drain contact CA and the fin-type active region F1, which are apart from each other with another source/drain region 130 therebetween.

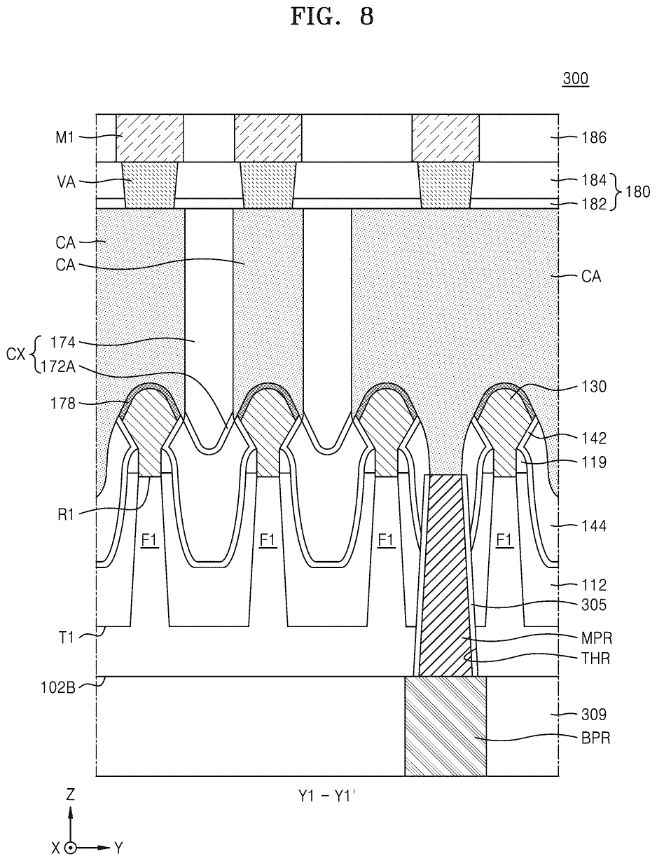

FIG. 8 is a cross-sectional view illustrating an integrated circuit device 300 according to some example embodiments. FIG. 8 illustrates components in a portion of the integrated circuit device 300, the portion corresponding to a cross-section taken along the line Y1-Y1′ of FIG. 2. In FIG. 8, the same reference numerals as in FIGS. 2 to 6 respectively denote the same members, and here, repeated descriptions thereof are omitted. The components shown in FIG. 8 may constitute a portion of the plurality of cells LC shown in FIG. 1.

Referring to FIG. 8, the integrated circuit device 300 has substantially the same configuration as the integrated circuit device 100 described with reference to FIGS. 2 to 6. However, the integrated circuit device 300 may include a power rail wiring line MPR, which passes through the substrate 102 in the vertical direction (the Z direction) from the backside surface 102B of the substrate 102. The power rail wiring line MPR may be formed in a through-region THR, which passes through a portion of the substrate 102 and a portion of each of the device isolation film 112, the insulating liner 142, and the inter-gate dielectric 144 in the vertical direction (the Z direction) from the backside surface 102B of the substrate 102. The power rail wiring line MPR may be connected to at least one source/drain contact CA selected from the plurality of source/drain contacts CA.

In some example embodiments, the power rail wiring line MPR may constitute the ground line VSS shown in FIG. 1. The power rail wiring line MPR may include a metal wiring layer and a conductive barrier layer surrounding the metal wiring layer. The metal wiring layer may include Ru, Co, W, or a combination thereof. The conductive barrier layer may include Ti, TiN, Ta, TaN, or a combination thereof. An insulating liner 305 may be arranged between a sidewall of the power rail wiring line MPR and the substrate 102. The insulating liner 305 may include silicon nitride, silicon oxide, SiOC, SiOCN, SiCN, SiBN, SiON, SiBCN, SiOF, SiOCH, or a combination thereof.

The backside surface 102B of the substrate 102 may be covered by a backside insulating film 309. A backside power rail BPR may pass through the backside insulating film 309 in the vertical direction (the Z direction) to be connected to the power rail wiring line MPR. The backside insulating film 309 may include a silicon oxide film, a silicon nitride film, a silicon carbide film, a low-k film, or a combination thereof. The low-k film may include, but is not limited to, fluorine-doped silicon oxide, organosilicate glass, a carbon-doped oxide, porous silicon oxide, porous organosilicate glass, a spin-on organic polymeric dielectric, a spin-on silicon-based polymeric dielectric, or a combination thereof.

The backside power rail BPR and the backside insulating film 309 on the backside surface 102B of the substrate 102 may be covered by a backside wiring structure (not shown). The backside wiring structure may include wiring layers connected to the backside power rail BPR.

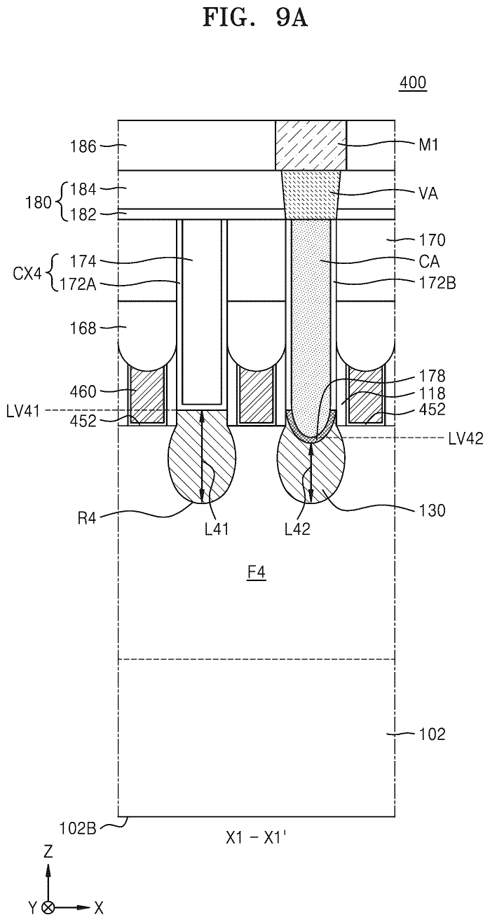

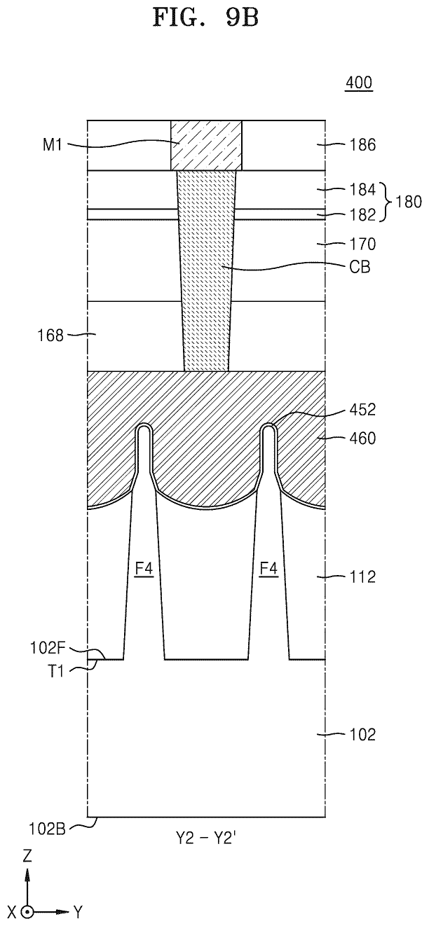

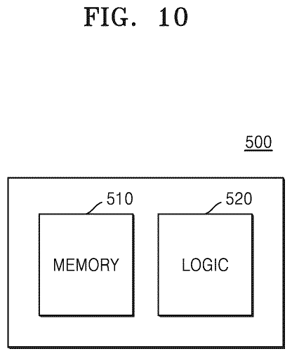

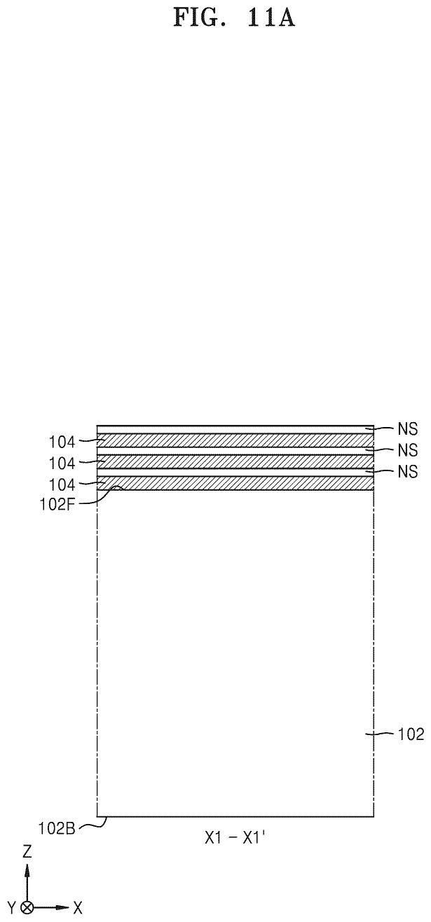

FIGS. 9A and 9B are cross-sectional views illustrating an integrated circuit device 400 according to some example embodiments. FIG. 9A illustrates a cross-sectional configuration of a portion of the integrated circuit device 400, which corresponds to a cross-section taken along the line X1-X1′ of FIG. 2, and FIG. 9B illustrates a cross-sectional configuration of a portion of the integrated circuit device 400, which corresponds to a cross-section taken along the line Y2-Y2′ of FIG. 2. In FIGS. 9A and 9B, the same reference numerals as in FIGS. 2 to 6 respectively denote the same members, and here, repeated descriptions thereof are omitted.

Referring to FIGS. 9A and 9B, the integrated circuit device 400 may include a fin field-effect transistor (FinFET) device. Components shown in FIGS. 9A and 9B may constitute a portion of the plurality of cells LC shown in FIG. 1.

The integrated circuit device 400 may include a plurality of fin-type active regions F4 protruding from the substrate 102. Each of the plurality of fin-type active regions F4 may have the same or substantially the same configuration as the fin-type active region F1 described with reference to FIGS. 2, 3, 5, and 6. The device isolation film 112 may be arranged between each of the plurality of fin-type active regions F4 and may cover a lower sidewall of each of the plurality of fin-type active regions F4.

A plurality of gate dielectric films 452 and a plurality of gate lines 460 may extend lengthwise in the second horizontal direction (the Y direction) on or over the plurality of fin-type active regions F4 and the device isolation film 112. The plurality of gate dielectric films 452 and the plurality of gate lines 460 may cover an upper surface and both sidewalls of each of the plurality of fin-type active regions F4 and the upper surface of the device isolation film 112. The plurality of gate dielectric films 452 and the plurality of gate lines 460 may respectively have the same or substantially the same configurations as the gate dielectric film 152 and the gate line 160, which are described with reference to FIGS. 2 to 6. A plurality of MOS transistors may be formed along the plurality of gate lines 460. Each of the plurality of MOS transistors may include a 3-dimensional-structure MOS transistor in which a channel is formed at the upper surface and both sidewalls of each of the plurality of fin-type active regions F4. Each of the plurality of MOS transistors may include an NMOS transistor, a PMOS transistor, or a combination thereof.

A plurality of main insulating spacers 118 may respectively cover both sidewalls of each of the plurality of gate lines 460. The plurality of gate lines 460, the plurality of gate dielectric films 452, and the plurality of main insulating spacers 118 may each be covered by the capping insulating pattern 168.

A plurality of recess regions R4 may be formed in the upper surface of each of the plurality of fin-type active regions F4. The plurality of source/drain regions 130 may be respectively arranged in the plurality of recess regions R4. The gate line 460 and the source/drain region 130 may be apart from each other with the gate dielectric film 452 and the main insulating spacer 118 therebetween.

As shown in FIG. 9A, the integrated circuit device 400 may include a contact isolation insulating structure CX4, which is arranged to overlap the source/drain region 130 on the fin-type active region F4 in the vertical direction (the Z direction), and a source/drain contact CA, which is arranged to overlap the source/drain region 130 on the fin-type active region F4 in the vertical direction (the Z direction).

The contact isolation insulating structure CX4 may have the same or substantially the same configuration as the contact isolation insulating structure CX described with reference to FIGS. 2, 4, and 5. The contact isolation insulating structure CX4 may include a first isolation insulating liner 172A and a contact isolation insulating pattern 174. Detailed configurations of the first isolation insulating liner 172A and the contact isolation insulating pattern 174 are the same as those described with reference to FIGS. 2, 4, and 5.

A vertical level LV41 of the lowermost surface of a portion, which is arranged on the source/drain region 130, of the contact isolation insulating structure CX4 overlapping the fin-type active region F4 in the vertical direction (the Z direction) may be farther from the fin-type active region F4 than a vertical level LV42 of the lowermost surface of a portion, which is arranged on the source/drain region 130, of the source/drain contact CA overlapping the fin-type active region F4 in the vertical direction (the Z direction). Therefore, a first length L41, in the vertical direction (the Z direction), of the source/drain region 130 arranged on the fin-type active region F4 to overlap the contact isolation insulating structure CX4 may be greater than a second length L42, in the vertical direction (the Z direction), of the source/drain region 130 arranged on the fin-type active region F4 to overlap the source/drain contact CA. Therefore, because the source/drain region 130 overlapping the contact isolation insulating structure CX4, among the plurality of source/drain regions 130, has a relatively large volume, the source/drain region 130 may induce sufficient strain to increase carrier mobility in a channel region, which is adjacent to the source/drain region 130, of the fin-type active region F4 according to the channel type of a transistor.

A separation distance in the vertical direction (the Z direction) between the contact isolation insulating structure CX4 and the fin-type active region F4, which are apart from each other with one source/drain region 130 on the fin-type active region F4 therebetween, may be greater than a separation distance in the vertical direction (the Z direction) between the source/drain contact CA and the fin-type active region F4, which are apart from each other with another source/drain region 130 therebetween.

As shown in FIG. 9A, each of the plurality of source/drain regions 130 may be connected to a source/drain via contact VA through the source/drain contact CA. As shown in FIG. 9B, a gate contact CB may be arranged on the gate line 460. Regarding detailed configurations of the plurality of source/drain regions 130, the plurality of source/drain contacts CA, and the gate contact CB, a reference may be made to the descriptions made with reference to FIGS. 3 to 6.

Similar to the integrated circuit device 100 described with reference to FIGS. 2 to 6, each of the integrated circuit devices 200, 300, and 400 described with reference to FIGS. 7A to 9B includes the plurality of source/drain contacts CA, which are respectively connected to the plurality of source/drain regions 130, and the plurality of contact isolation insulating structures CX, CX2, or CX4, which are arranged one-by-one between each of the plurality of source/drain contacts CA. The plurality of source/drain contacts CA and the plurality of contact isolation insulating structures CX, CX2, or CX4 may be aligned in a row on a straight line, which follows the second horizontal direction (the Y direction), between a pair of gate lines 160 or 460 adjacent to each other. In the integrated circuit devices 200, 300, and 400, the plurality of source/drain contacts CA and the plurality of contact isolation insulating structures CX, CX2, or CX4, which are aligned in a row on a straight line following the second horizontal direction (the Y direction), may be formed by forming a line-shaped space (for example, the line-shaped space LH shown in FIGS. 19B and 19C), which extends lengthwise in the second horizontal direction (the Y direction), in advance and then filling the line-shaped space with the plurality of source/drain contacts CA and the plurality of contact isolation insulating structures CX, CX2, or CX4. According to the inventive concepts, after the line-shaped space is formed, the plurality of source/drain contacts CA and the plurality of contact isolation insulating structures CX, CX2, or CX4 are formed in the line-shaped space, whereby a relatively large contact area between the source/drain region 130 and the source/drain contact CA may be secured, as compared with a general process, for example, a process of forming a plurality of relatively narrow and deep holes for forming the plurality of source/drain contacts CA and then forming a plurality of source/drain contacts to be arranged one-by-one in each of the plurality of holes. Therefore, the contact resistance between the source/drain contact CA and the source/drain region 130 may be relatively reduced, and thus, even when each of the integrated circuit devices 200, 300, and 400 has a device area reduced due to down-scaling, the reliability of each of the integrated circuit devices 200, 300, and 400 may improve.

FIG. 10 is a block diagram of an integrated circuit device 500 according to some example embodiments.

Referring to FIG. 10, the integrated circuit device 500 may include a memory area 510 and a logic area 520. At least one of the memory area 510 and the logic area 520 may include at least one of the configurations of the integrated circuit devices 100, 200, 300, and 400 described with reference to FIGS. 2 to 9B.

The memory area 510 may include at least one of static random-access memory (SRAM), dynamic RAM (DRAM), magnetic RAM (MRAM), resistive RAM (RRAM), and phase-change RAM (PRAM). For example, the memory area 510 may include SRAM. The logic area 520 may include standard cells performing intended logical functions, such as a counter, a buffer, and the like. The standard cells may include various logic cells including a plurality of circuit elements, such as a transistor, a register, and the like. Each of the logic cells may constitute, for example, an AND, a NAND, an OR, a NOR, an XOR, an XNOR, an INV, an ADD, a BUF, a DLY, a FIL, an MXT/MXIT, an OAI, an AO, an AOI, a D flip-flop, a reset flip-flop, a master-slave flip-flop, a latch, or the like.

Any or all of the elements described with reference to FIG. 10 may communicate with any or all other elements described with reference to FIG. 10. For example, any element may engage in one-way and/or two-way and/or broadcast communication with any or all other elements in FIG. 10, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

Next, a method of fabricating an integrated circuit device, according to some example embodiments, is described in detail.

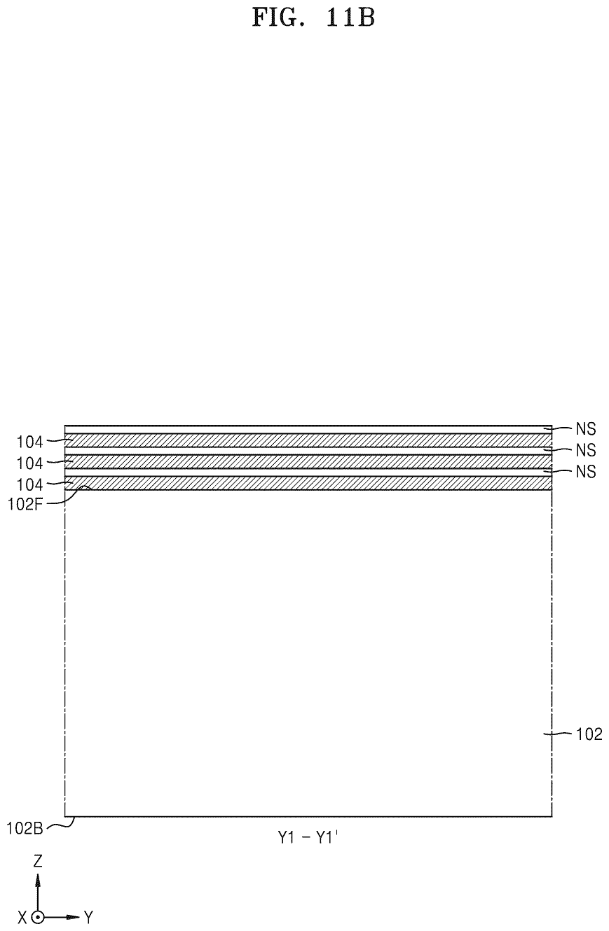

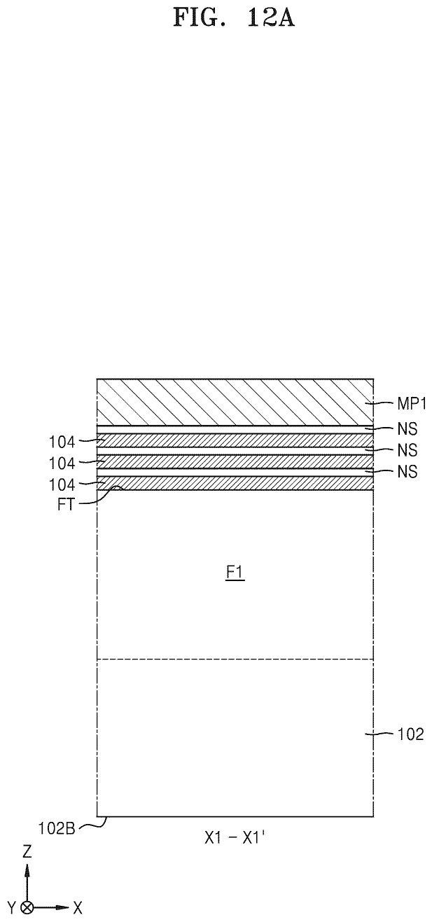

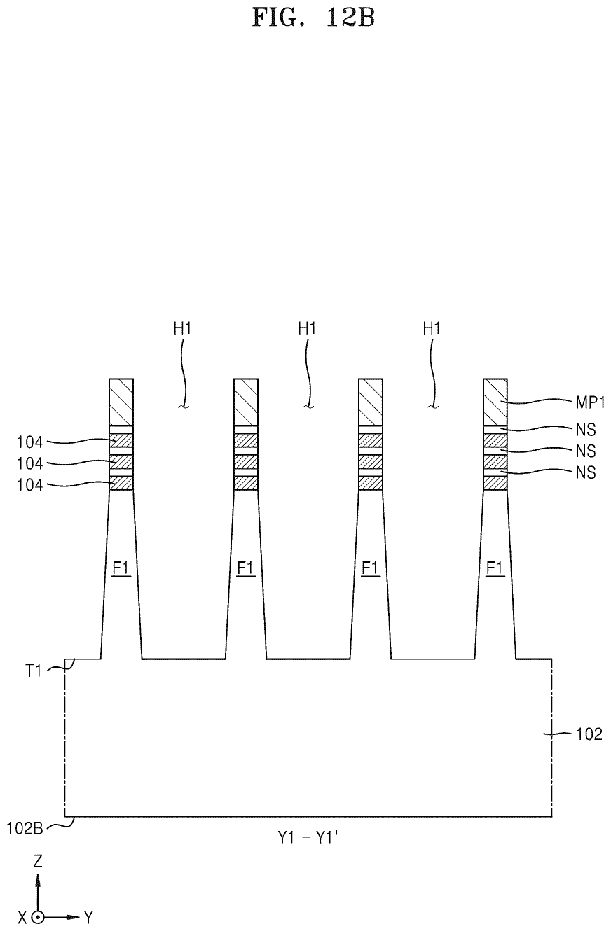

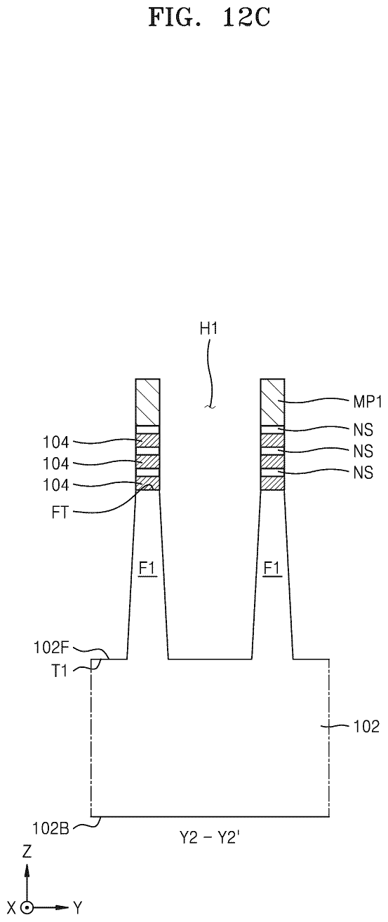

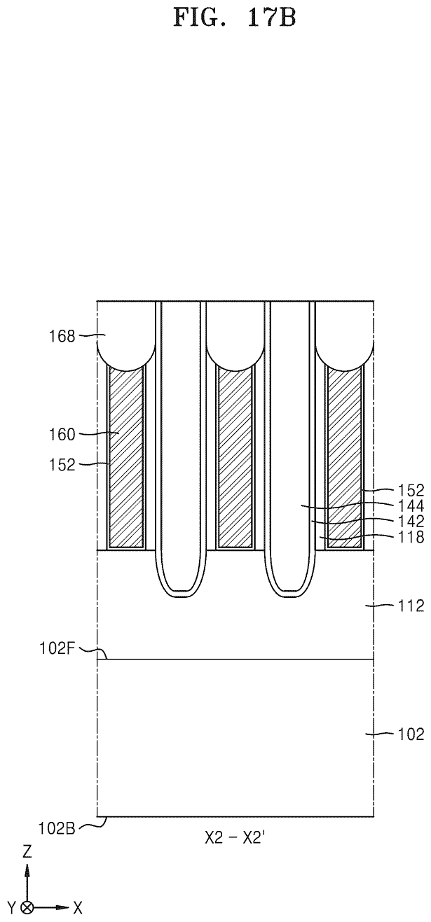

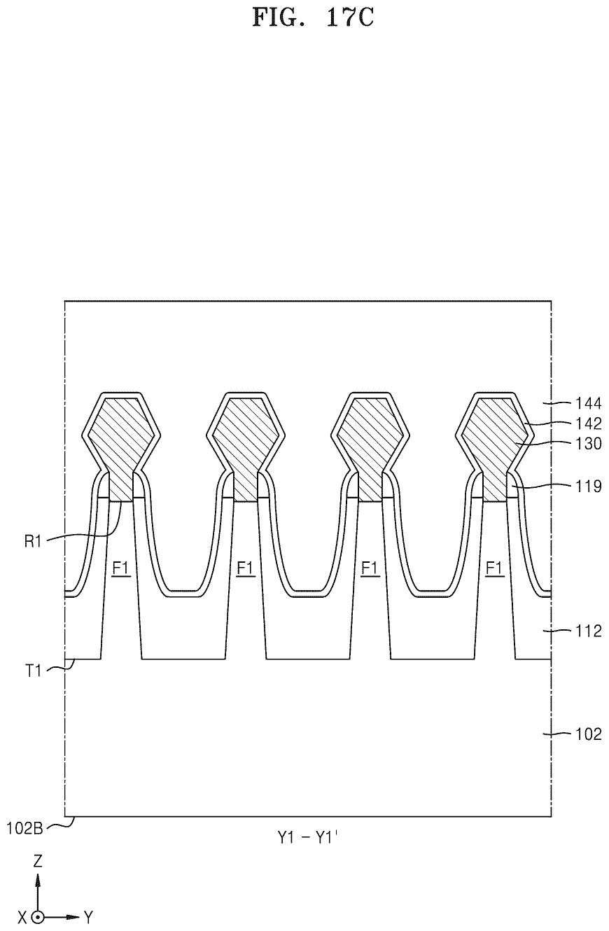

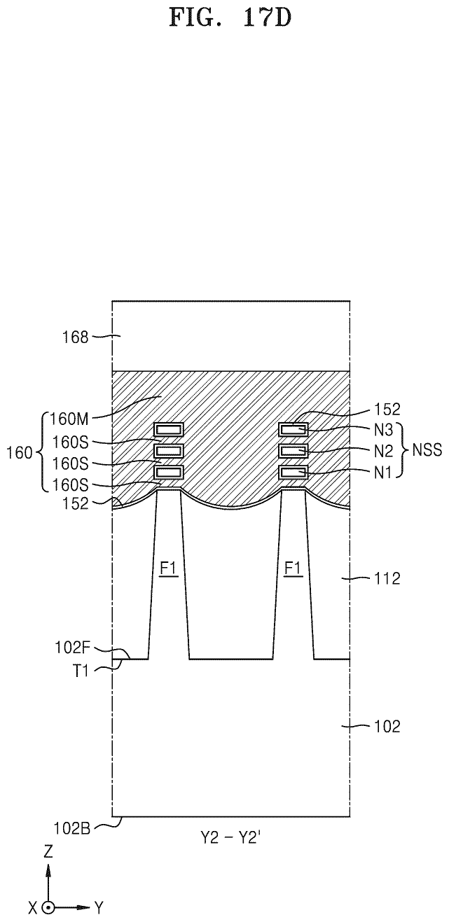

FIGS. 11A to 26C are diagrams respectively illustrating a sequence of processes of a method of fabricating an integrated circuit device, according to some example embodiments. For example, FIGS. 11A, 12A, 14A, 15A, 16A, 17A, 18A, 19A, 20A, 21A, 22A, 23A, 24A, 25A, and 26A are cross-sectional views respectively illustrating cross-sectional structures of a region corresponding to a cross-section taken along the line X1-X1′ of FIG. 2, according to the sequence of processes. FIGS. 17B, 18B, 19B, 20B, 21B, 22B, 23B, 24B, 25B, and 26B are cross-sectional views respectively illustrating cross-sectional structures of a region corresponding to a cross-section taken along the line X2-X2′ of FIG. 2, according to the sequence of processes. FIGS. 11B, 12B, 13, 14B, 15B, 16B, 17C, 18C, 19C, 20C, 21C, 22C, 23C, 24C, 25C, and 26C are cross-sectional views respectively illustrating cross-sectional structures of a region corresponding to a cross-section taken along the line Y1-Y1′ of FIG. 2, according to the sequence of processes. FIGS. 12C, 14C, 15C, 17D, and 18D are cross-sectional views respectively illustrating cross-sectional structures of a region corresponding to a cross-section taken along the line Y2-Y2′ of FIG. 2. An example of a method of fabricating the integrated circuit device 100 described with reference to FIGS. 2 to 6 is described with reference to FIGS. 11A to 26C. In FIGS. 11A to 26C, the same reference numerals as in FIGS. 2 to 6 respectively denote the same members, and here, repeated descriptions thereof are omitted.

Referring to FIGS. 11A and 11B, the substrate 102 having the frontside surface 102F and the backside surface 102B may be prepared, and a plurality of sacrificial semiconductor layers 104 and a plurality of nanosheet semiconductor layers NS may be alternately stacked one-by-one on the frontside surface 102F of the substrate 102.

Each of the plurality of sacrificial semiconductor layers 104 and each of the plurality of nanosheet semiconductor layers NS may respectively include semiconductor materials having different etch selectivities. In some example embodiments, each of the plurality of nanosheet semiconductor layers NS may include a Si layer, and each of the plurality of sacrificial semiconductor layers 104 may include a SiGe layer. In some example embodiments, Ge may be present in a constant amount in the plurality of sacrificial semiconductor layers 104. The SiGe layer constituting each of the plurality of sacrificial semiconductor layers 104 may include Ge in a constant amount selected from a range of about 5 at % to about 50 at %, for example, about 10 at % to about 40 at %. The amount of Ge in the SiGe layer constituting each of the plurality of sacrificial semiconductor layers 104 may be variously selected, as needed.

Referring to FIGS. 12A, 12B, and 12C, a first mask pattern MP1 having a plurality of openings H1 may be formed on the resulting product of FIGS. 11A and 11B. Next, each of the plurality of sacrificial semiconductor layers 104, the plurality of nanosheet semiconductor layers NS, and the substrate 102 may be partially etched from exposed portions of the resulting product of FIGS. 11A and 11B through the plurality of openings H1 by using the first mask pattern MP1 as an etch mask, thereby forming a plurality of fin-type active regions F1 in the substrate 102. A plurality of trench regions T1 may be defined on the substrate 102 by the plurality of fin-type active regions F1. In some example embodiments, the first mask pattern MP1 may include a stack structure of a silicon oxide film pattern and a silicon nitride film pattern. The first mask pattern MP1 may include portions extending parallel to each other in the first horizontal direction (X direction) over the substrate 102. A stack structure of the plurality of sacrificial semiconductor layers 104 and the plurality of nanosheet semiconductor layers NS may remain on the fin top surface FT of each of the plurality of fin-type active regions F1.

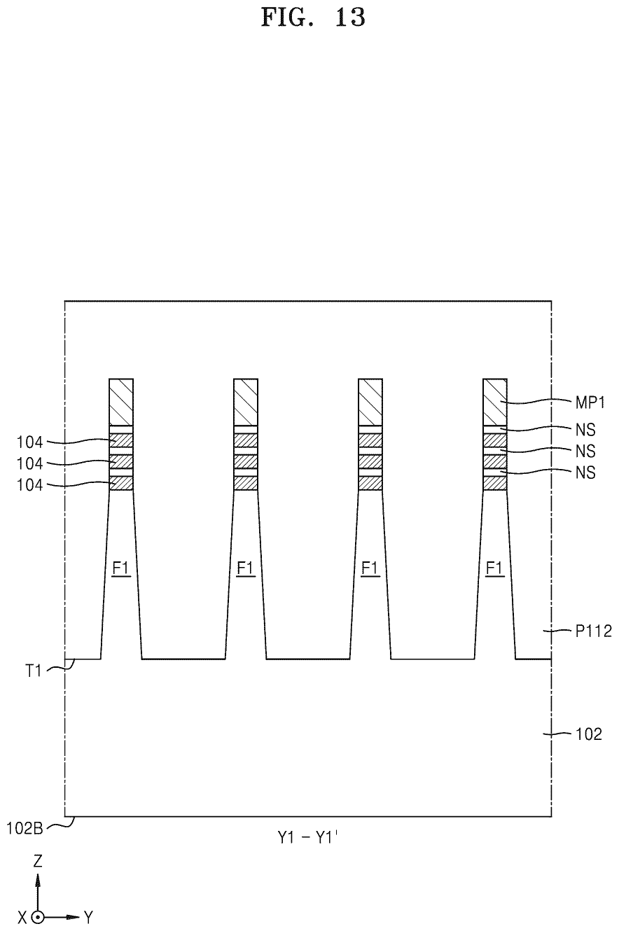

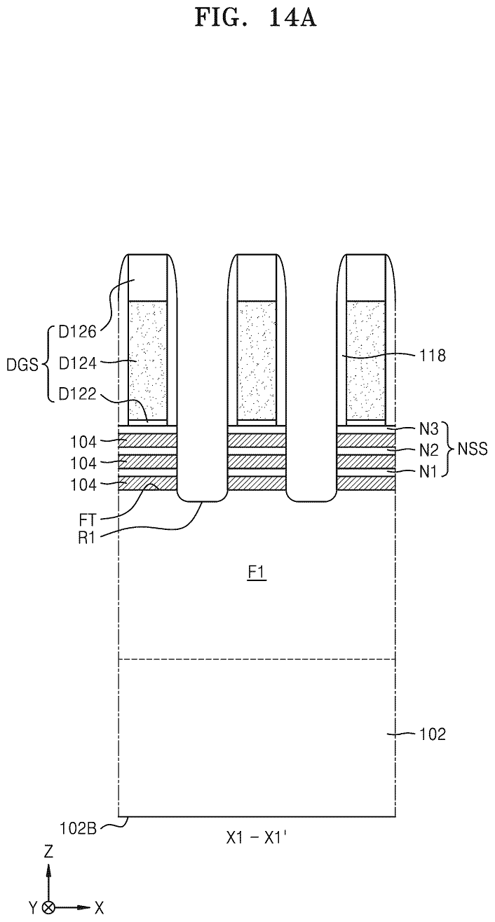

Referring to FIG. 13, a device isolation insulating film P112 may be formed on the resulting product of FIGS. 12A, 12B, and 12C. The device isolation insulating film P112 may be formed to a thickness sufficient to fill the plurality of trench regions T1. In some example embodiments, the device isolation insulating film P112 may include, but is not limited to, a silicon oxide film.

To form the device isolation insulating film P112, a plasma-enhanced chemical vapor deposition (PECVD) process, an HDP CVD process, an inductively coupled plasma CVD (ICP CVD) process, a capacitively coupled plasma CVD (CCP CVD) process, an FCVD process, a spin-coating process, or the like may be used.

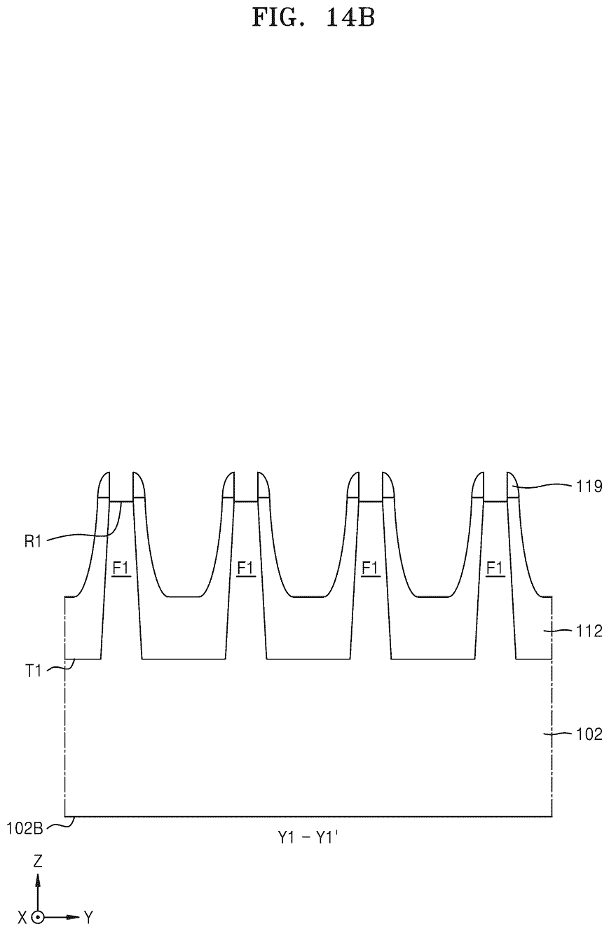

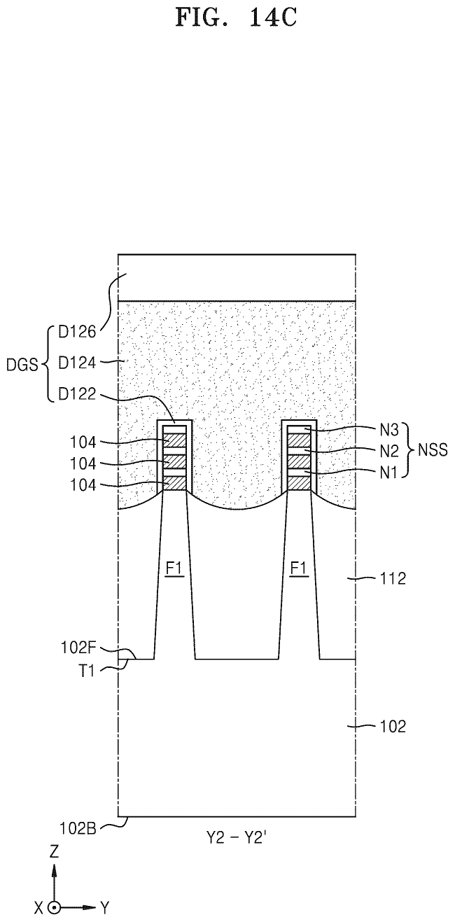

Referring to FIGS. 14A, 14B, and 14C, the resulting product of FIG. 13 may be planarized to expose an upper surface of the first mask pattern MP1, followed by removing the exposed first mask pattern MP1, and then, a recess process for removing a portion of the device isolation insulating film P112 may be performed, thereby forming the device isolation film 112, which includes the remaining portion of the device isolation insulating film P112. As a result, the plurality of sacrificial semiconductor layers 104 and the plurality of nanosheet semiconductor layers NS may protrude from the upper surface of the device isolation film 112.

To perform the recess process of the device isolation insulating film P112, a dry etching process, a wet etching process, or a combination process of dry etching and wet etching may be used. Here, a wet etching process using NH₄OH, tetramethylammonium hydroxide (TMAH), potassium hydroxide (KOH), or the like as an etchant or a dry etching process by a method, such as ICP, transformer coupled plasma (TCP), electron cyclotron resonance (ECR), or reactive ion etch (RIE), may be used. When the recess process of the device isolation insulating film P112 is performed by a dry etching process, a fluorine-containing gas, such as CF₄, a chlorine-containing gas, such as Cl₂, HBr, or the like may be used as an etching gas.

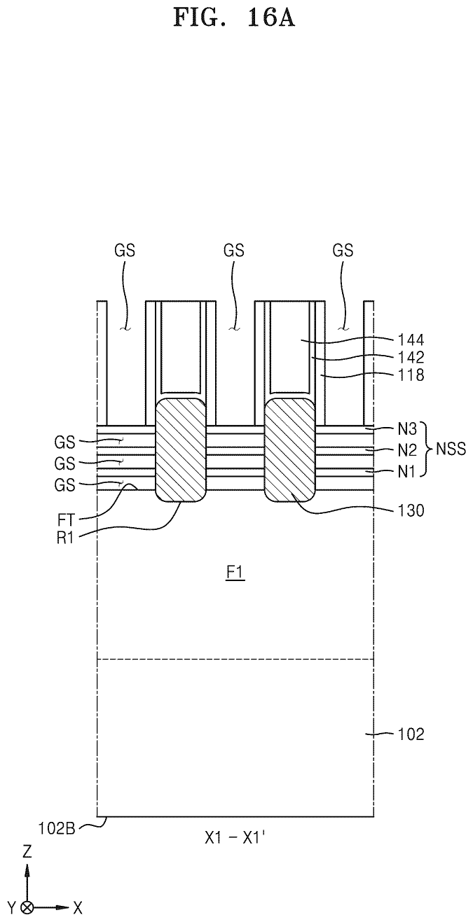

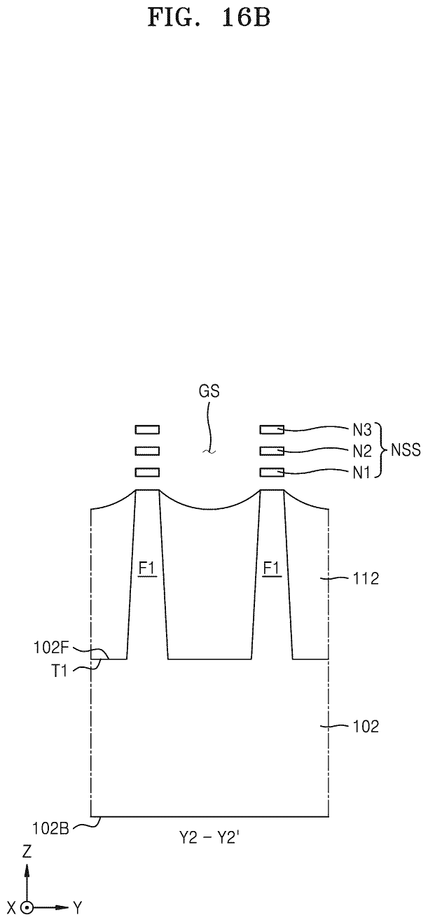

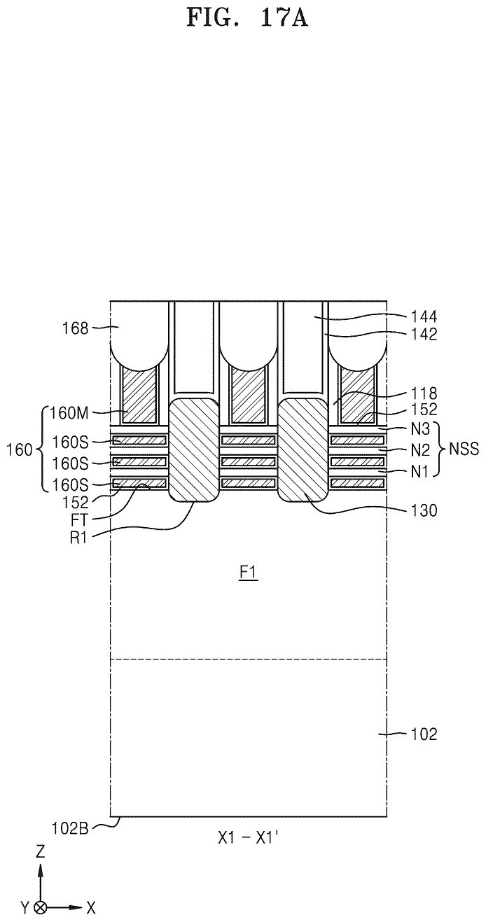

Next, a plurality of dummy gate structures DGS may be formed on a stack structure of the plurality of sacrificial semiconductor layers 104 and the plurality of nanosheet semiconductor layers NS. Each of the plurality of dummy gate structures DGS may be formed to extend lengthwise in the second horizontal direction (the Y direction). Each of the plurality of dummy gate structures DGS may have a structure in which an oxide film D122, a dummy gate layer D124, and a capping layer D126 are stacked in the stated order. In some example embodiments, the oxide film D122 may be obtained by oxidizing a surface of each of the plurality of sacrificial semiconductor layers 104 and the plurality of nanosheet semiconductor layers NS (see FIG. 16). The dummy gate layer D124 may include polysilicon, and the capping layer D126 may include a silicon nitride film.

The plurality of main insulating spacers 118 may be formed to cover both sidewalls of each of the plurality of dummy gate structures DGS, followed by etching a portion of each of the plurality of sacrificial semiconductor layers 104 and the plurality of nanosheet semiconductor layers NS and a portion of the fin-type active region F1 by using the plurality of dummy gate structures DGS and the plurality of main insulating spacers 118 as an etch mask, whereby the plurality of nanosheet semiconductor layers NS may be divided into the plurality of nanosheet stacks NSS, which each include the first nanosheet N1, the second nanosheet N2, and the third nanosheet N3, and the plurality of recesses R1 may be formed in an upper portion of the fin-type active region F1. To form the plurality of recesses R1, etching may be performed by dry etching, wet etching, or a combination thereof. After the plurality of recesses R1 are formed, the plurality of side insulating spacers 119 may be formed as shown in FIG. 14B, the plurality of side insulating spacers 119 being arranged on the device isolation film 112 on both sides of each fin-type active region F1 in the second horizontal direction (Y direction) to be respectively adjacent to the plurality of recesses R1.

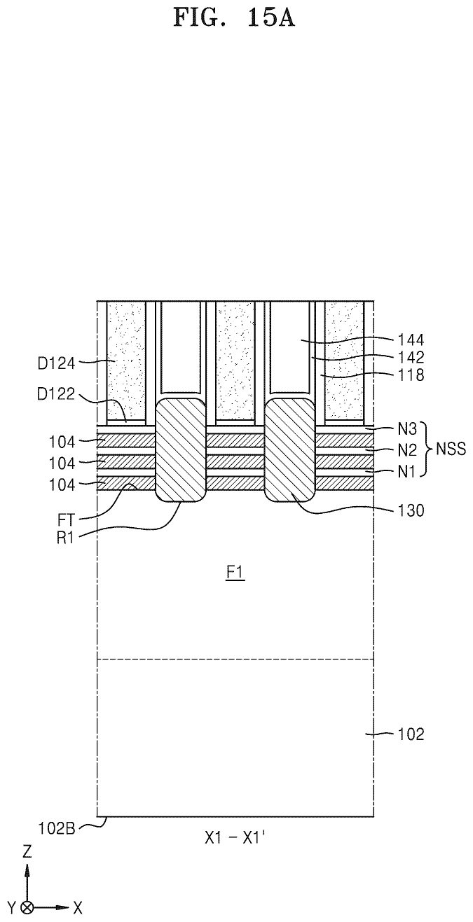

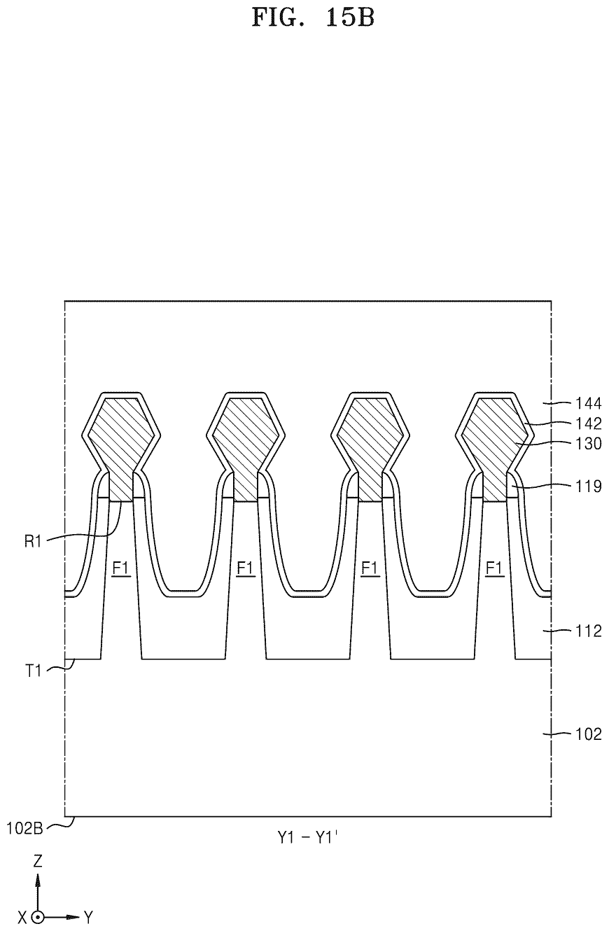

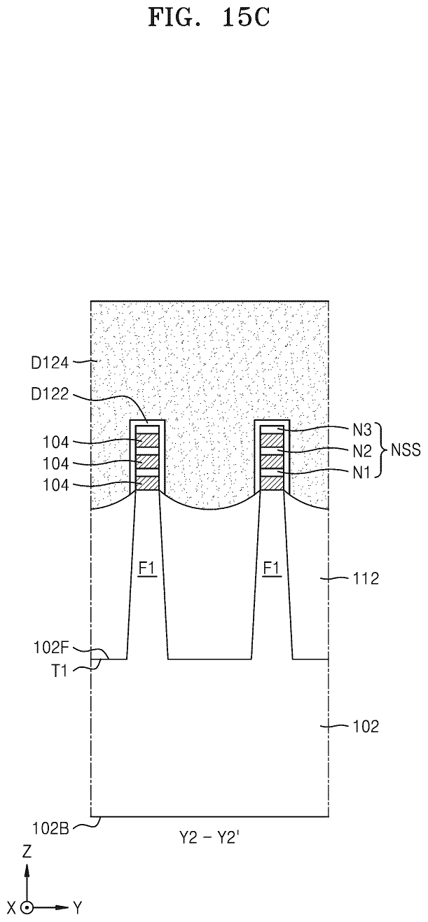

Referring to FIGS. 15A, 15B, and 15C, in the resulting product of FIGS. 14A, 14B, and 14C, the plurality of source/drain regions 130 may be formed to respectively fill the plurality of recesses R1. To form the plurality of source/drain regions 130, a semiconductor material may be epitaxially grown on an exposed surface of the fin-type active region F1 and an exposed sidewall of each of the first nanosheet N1, the second nanosheet N2, and the third nanosheet N3 of the nanosheet stack NSS in the plurality of recesses R1.

Next, the insulating liner 142 may be formed to cover a resulting product in which the plurality of source/drain regions 130 are formed, followed by forming the inter-gate dielectric 144 on the insulating liner 142, and then, each of the insulating liner 142 and the inter-gate dielectric 144 may be partially etched, thereby exposing upper surfaces of a plurality of capping layers D126. Next, the dummy gate layer D124 may be exposed by removing the plurality of capping layers D126, and the insulating liner 142 and the inter-gate dielectric 144 may be partially removed such that the upper surface of the inter-gate dielectric 144 and the upper surface of the dummy gate layer D124 are at an approximately equal level.

Referring to FIGS. 16A and 16B, a gate space GS may be prepared by removing the dummy gate layer D124 and the oxide film D122 thereunder from the resulting product of FIGS. 15A, 15B, and 15C, and the plurality of nanosheet stacks NSS may each be exposed by the gate space GS. Next, by removing the plurality of sacrificial semiconductor layers 104 remaining on the fin-type active region F1 through the gate space GS, the gate space GS may expand up to each space between the first nanosheet N1, the second nanosheet N2, and the third nanosheet N3 and a space between the first nanosheet N1 and the fin-type active region F1.

In some example embodiments, to selectively remove the plurality of sacrificial semiconductor layers 104, a difference in etch selectivity between each of the first nanosheet N1, the second nanosheet N2, the third nanosheet N3, and the fin-type active region F1 and each of the plurality of sacrificial semiconductor layers 104 may be used. To selectively remove the plurality of sacrificial semiconductor layers 104, a liquid-phase or gas-phase etchant may be used. In some example embodiments, to selectively remove the plurality of sacrificial semiconductor layers 104, a CH₃COOH-based etching solution, for example, an etching solution including a mixture of CH₃COOH, HNO₃, and HF, or an etching solution including a mixture of CH₃COOH, H₂O₂, and HF, may be used, but the inventive concepts is not limited thereto.

Referring to FIGS. 17A, 17B, 17C, and 17D, in the resulting product of FIGS. 16A and 16B, the gate dielectric film 152 may be formed to cover respective exposed surfaces of the first nanosheet N1, the second nanosheet N2, the third nanosheet N3, and the fin-type active region F1. To form the gate dielectric film 152, an ALD process may be used.

Next, the gate line 160 may be formed on the gate dielectric film 152 to fill the gate space GS (see FIGS. 16A and 16B), followed by partially removing each of the gate line 160, the gate dielectric film 152, and the main insulating spacer 118 from the upper surface thereof to reduce the height thereof, and then, the plurality of capping insulating patterns 168 may each be formed to cover the upper surface of each of the gate line 160, the gate dielectric film 152, and the main insulating spacer 118.

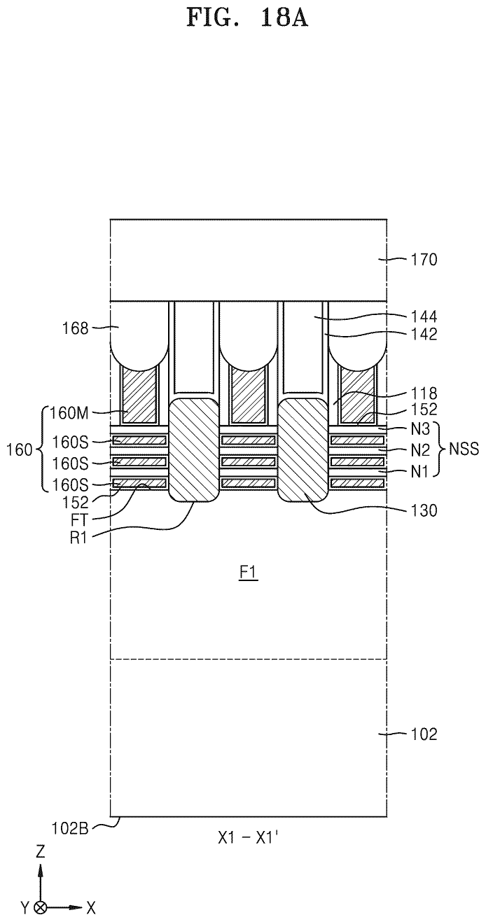

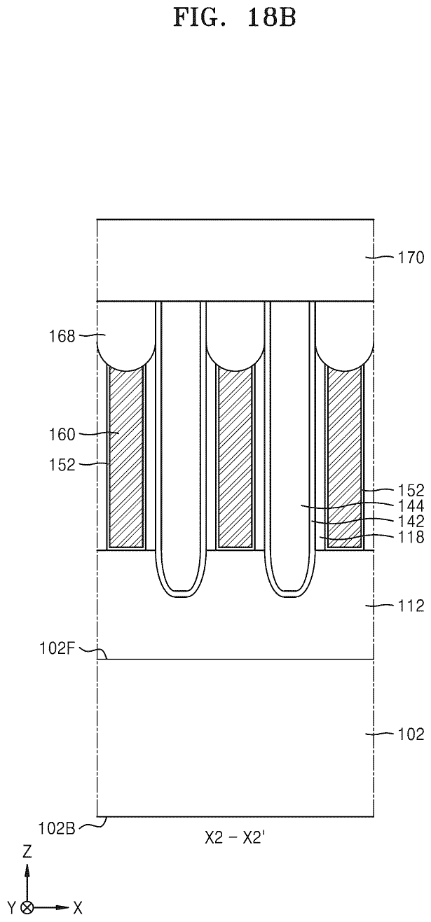

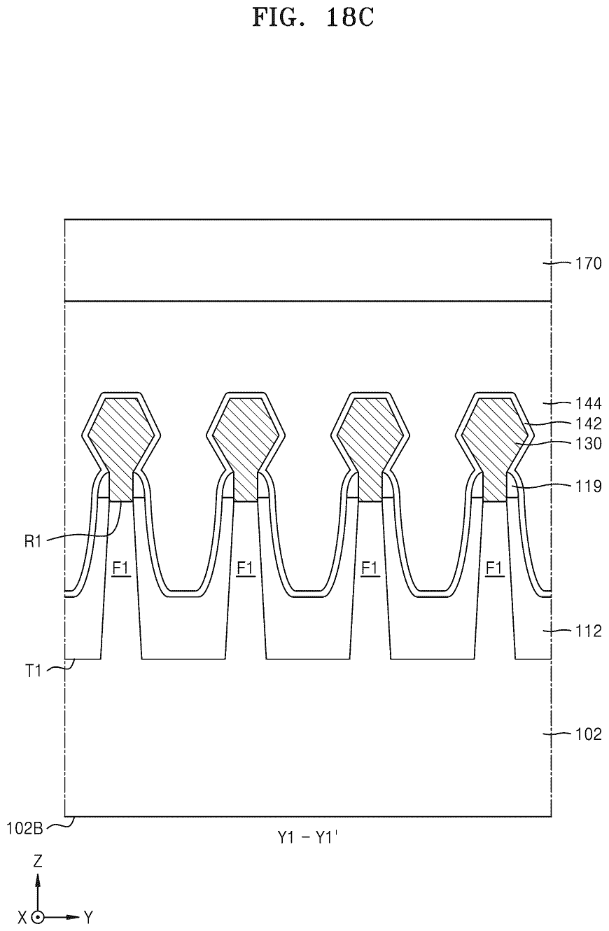

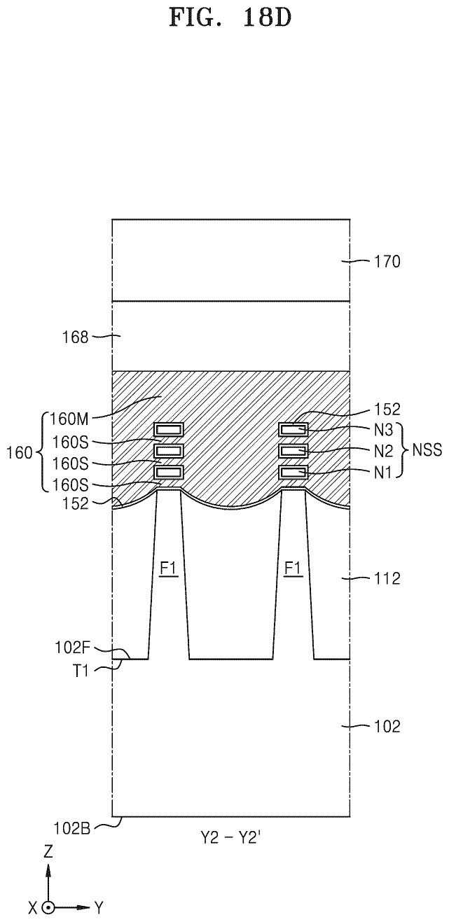

Referring to FIGS. 18A, 18B, 18C, and 18D, the first upper insulating film 170 may be formed on the resulting product of FIGS. 17A, 17B, 17C, and 17D.

Referring to FIGS. 19A, 19B, and 19C, a second mask pattern MP2 may be formed on the first upper insulating film 170, and each of the first upper insulating film 170, the insulating liner 142, and the inter-gate dielectric 144 may be partially etched by using the second mask pattern MP2 as an etch mask, thereby forming a plurality of line-shaped spaces LH, which respectively expose the plurality of source/drain regions 130. The plurality of line-shaped spaces LH may be formed such that each line-shaped space LH is arranged between a pair of gate lines 160 adjacent to each other and extends lengthwise in the second horizontal direction (the Y direction). The second mask pattern MP2 may include a hardmask pattern, a photoresist pattern, or a combination thereof. The hardmask pattern may include, but is not limited to, a silicon oxide film, a silicon nitride film, a silicon oxynitride film, or a combination thereof.

As shown in FIGS. 19B and 19C, a vertical level LV83 of the lowermost portion, which overlaps the device isolation film 112 in the vertical direction (the Z direction), of the upper surface of the inter-gate dielectric 144 exposed in each of the plurality of line-shaped spaces LH may be closer to the substrate 102 and the device isolation film 112 than a vertical level LV81 of the uppermost portion, which overlaps the device isolation film 112 in the vertical direction (the Z direction), of each of the plurality of source/drain regions 130 exposed in the plurality of line-shaped spaces LH. Such a resulting product may be obtained by controlling the etch selectivity between the inter-gate dielectric 144 and each of the plurality of source/drain regions 130 while an etching process for forming the plurality of line-shaped spaces LH is being performed.

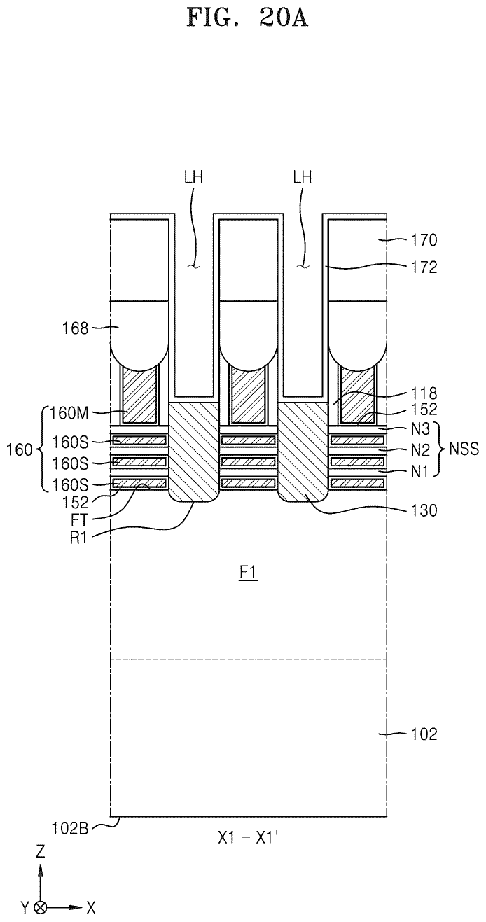

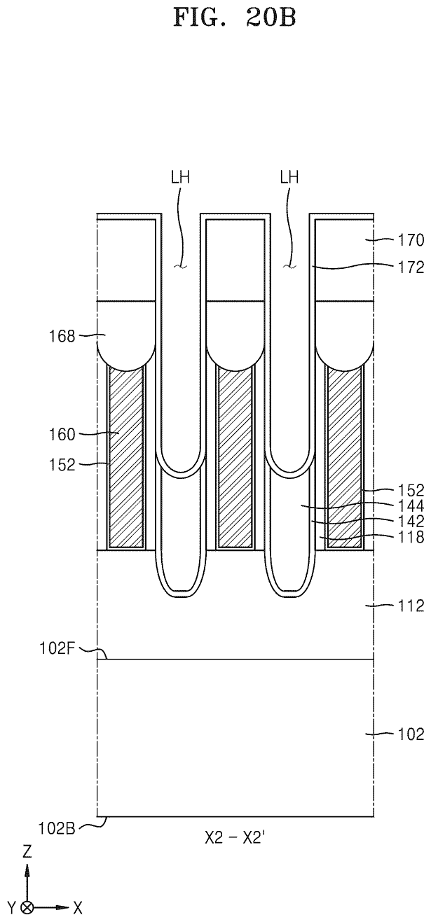

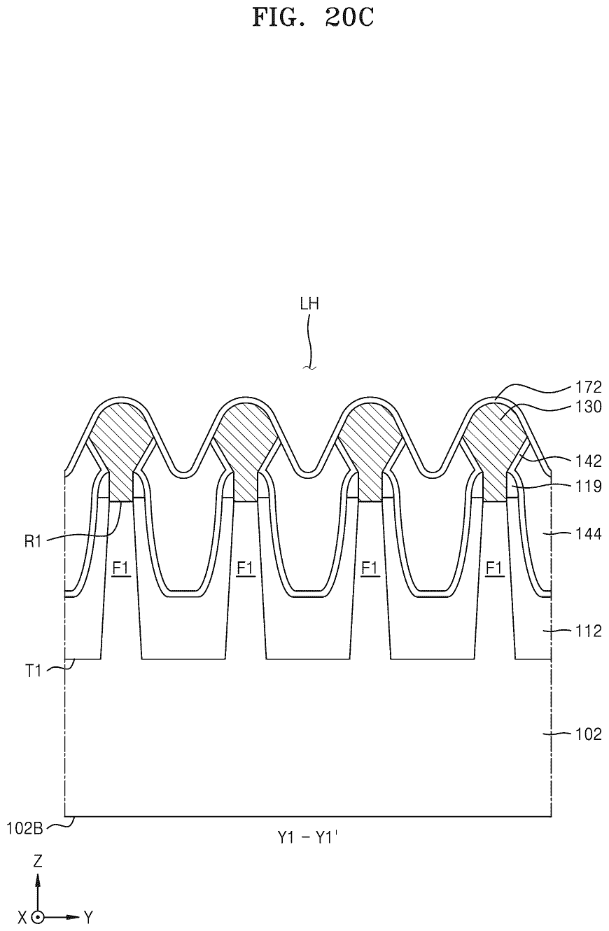

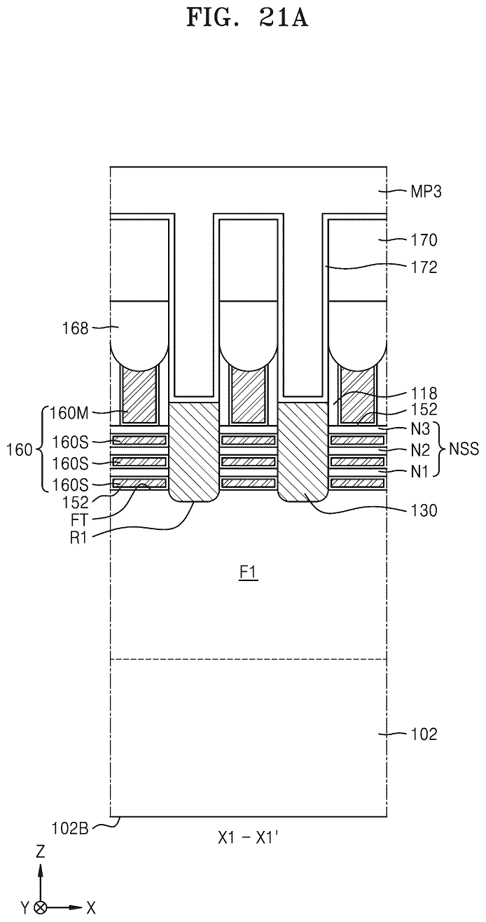

Referring to FIGS. 20A, 20B, and 20C, an isolation insulating liner 172 may be formed to conformally cover exposed surfaces in the entire surfaces of the resulting product of FIGS. 19A, 19B, and 19C. A constituent material of the isolation insulating liner 172 is the same as the constituent material of each of the first isolation insulating liner 172A and the second isolation insulating liner 172B, which are described with reference to FIGS. 3 and 4.

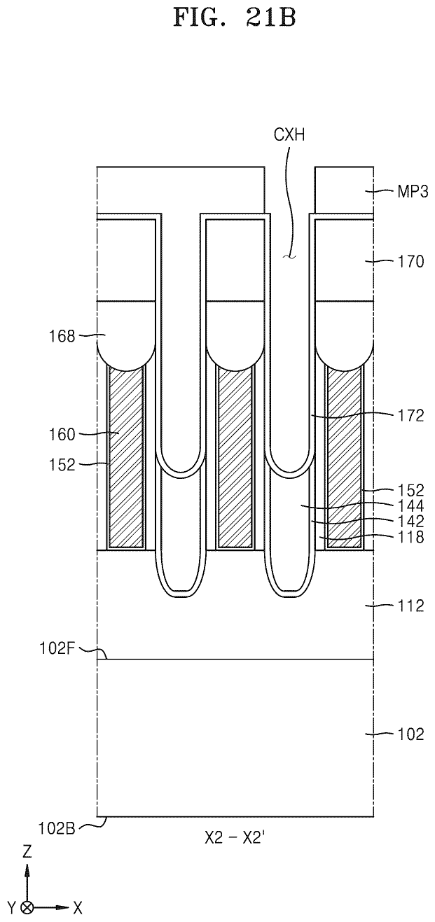

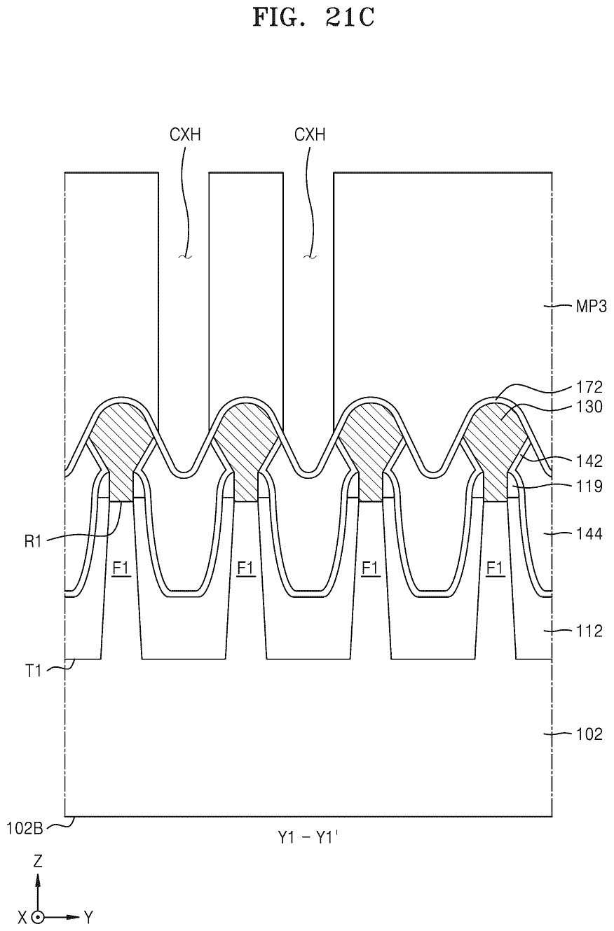

Referring to FIGS. 21A, 21B, and 21C, in the resulting product of FIGS. 20A, 20B, and 20C, a third mask pattern MP3 may be formed on the isolation insulating liner 172. In some example embodiments, the third mask pattern MP3 may include a carbon-containing film, such as a spin-on hardmask (SOH). The third mask pattern MP3 may include a plurality of isolation holes CXH. The plurality of isolation holes CXH may be formed to respectively correspond to regions in which the plurality of contact isolation insulating structures CX (see FIGS. 2, 4, and 5) are arranged. Some portions of the isolation insulating liner 172 may be exposed by a bottom portion of each of the plurality of isolation holes CXH and both inner sidewalls, in the first horizontal direction (the X direction), of each of the plurality of isolation holes CXH.

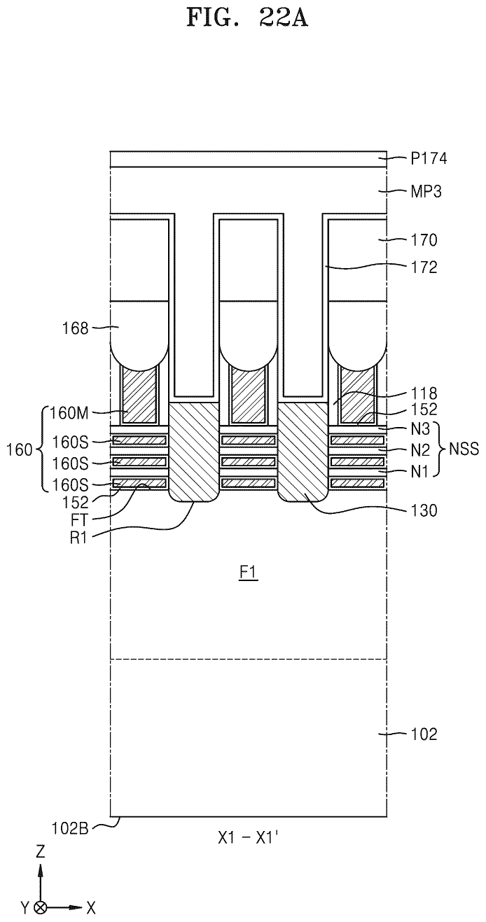

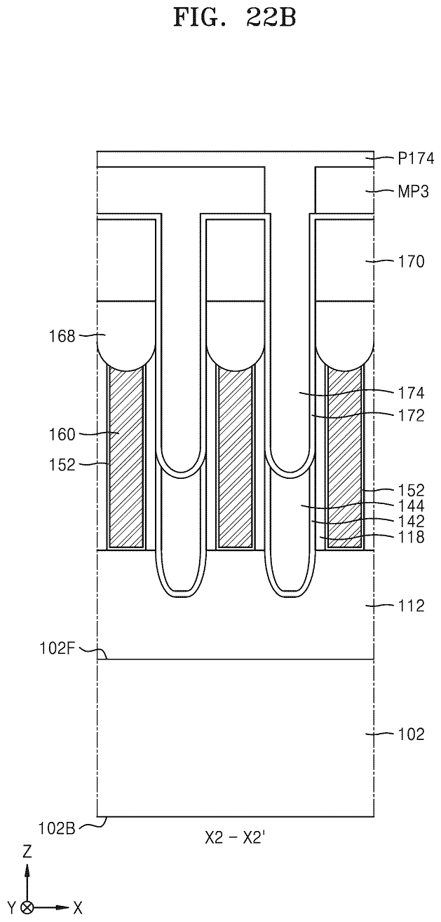

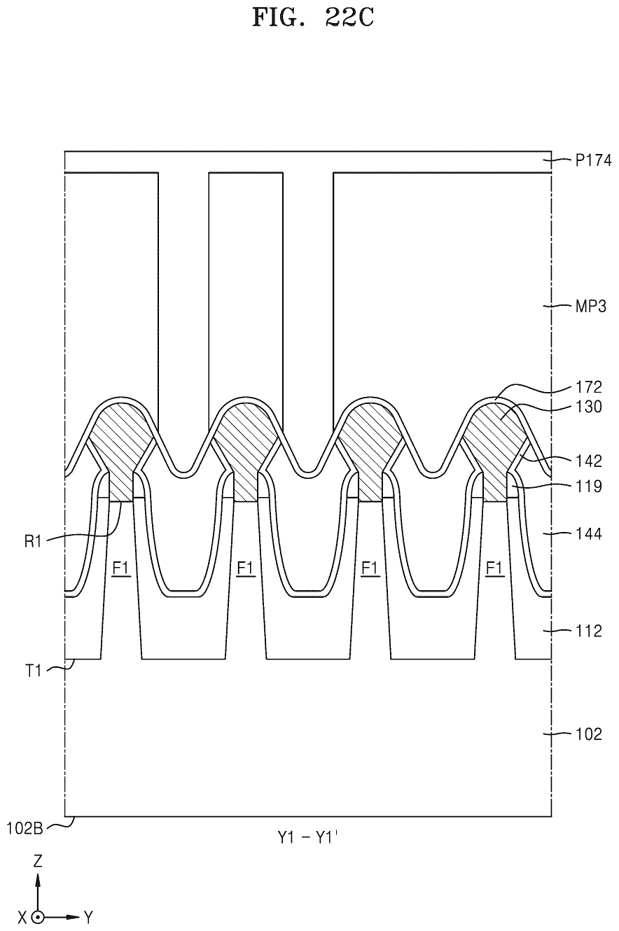

Referring to FIGS. 22A, 22B, and 22C, in the resulting product of FIGS. 21A, 21B, and 21C, a contact isolation insulating films P174 may be formed to fill the plurality of isolation holes CXH. A constituent material of the contact isolation insulating film P174 is the same as the constituent material of the contact isolation insulating pattern 174 described with reference to FIGS. 4 and 5.

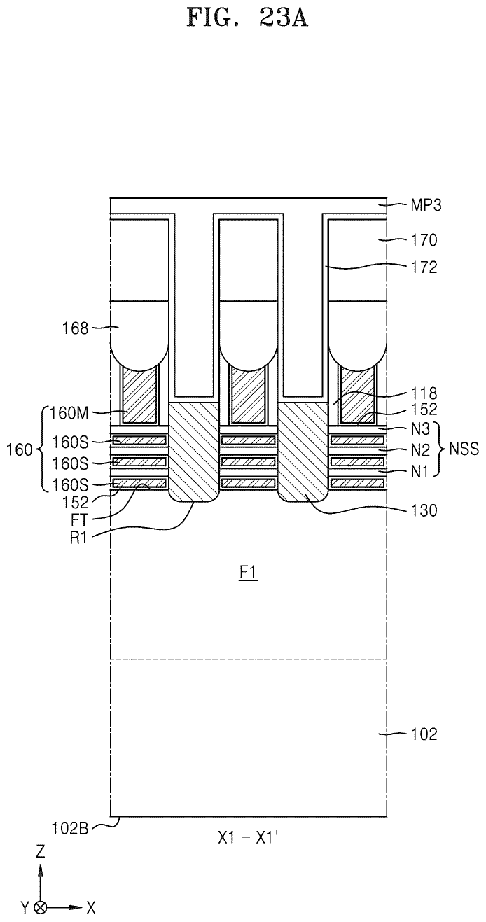

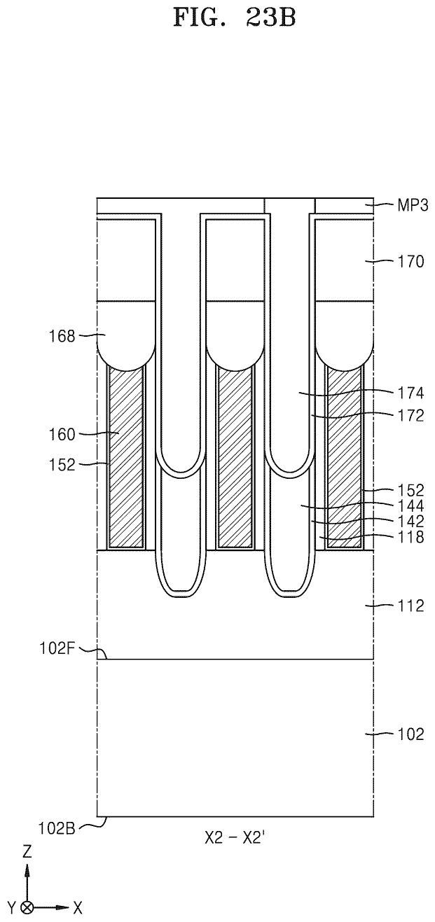

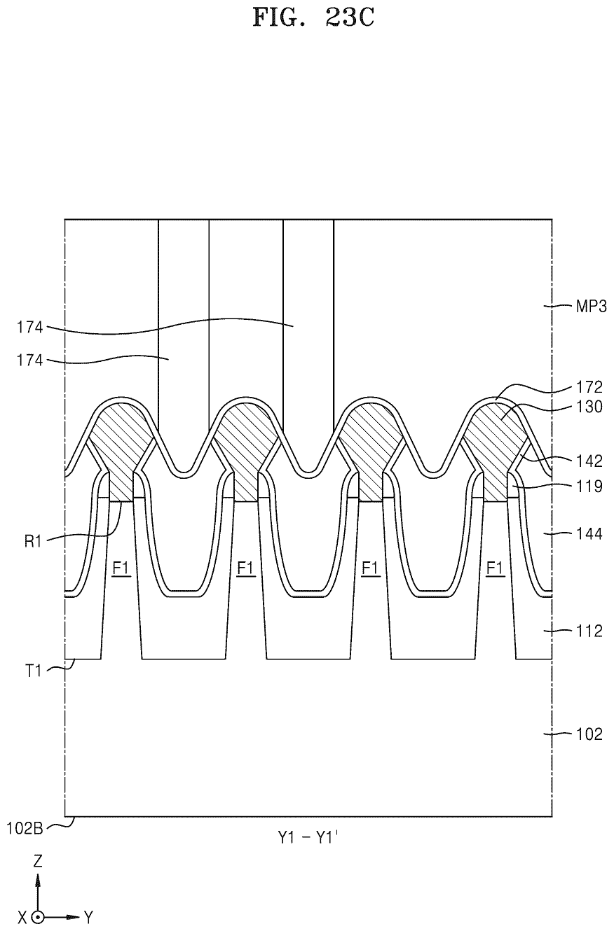

Referring to FIGS. 23A, 23B, and 23C, in the resulting product of FIGS. 22A, 22B, and 22C, an upper portion of the contact isolation insulating film P174 may be removed by etch-back, thereby exposing the upper surface of the third mask pattern MP3. As a result, the plurality of contact isolation insulating patterns 174 may be obtained from the contact isolation insulating film P174 to respectively fill the plurality of isolation holes CXH.

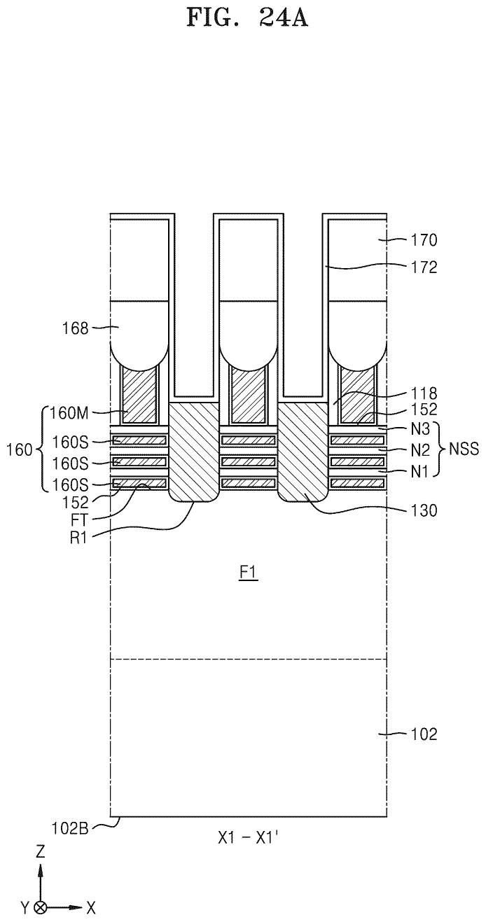

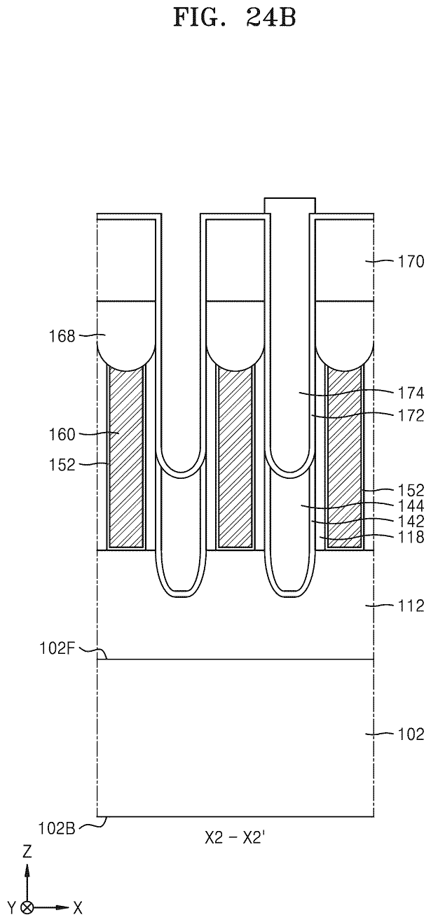

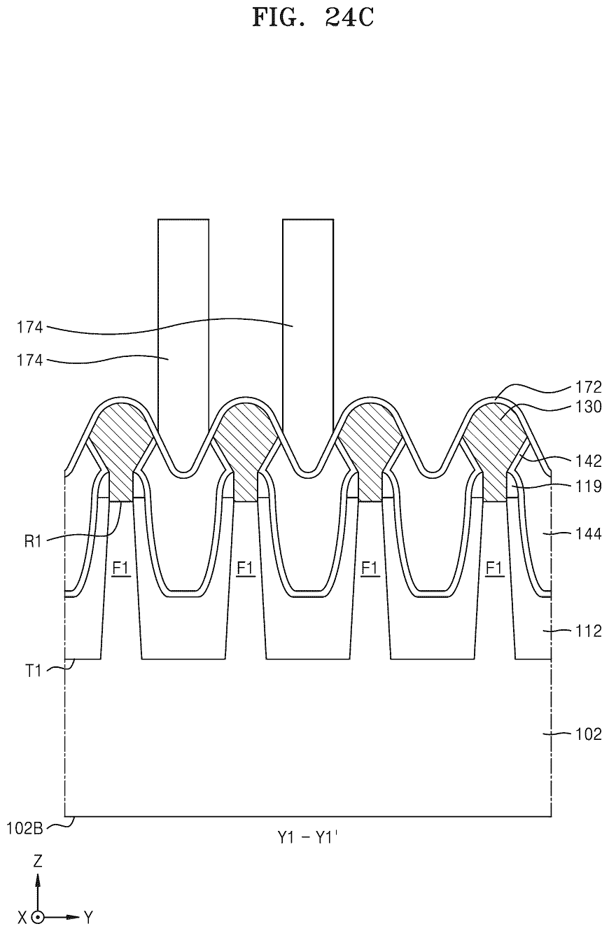

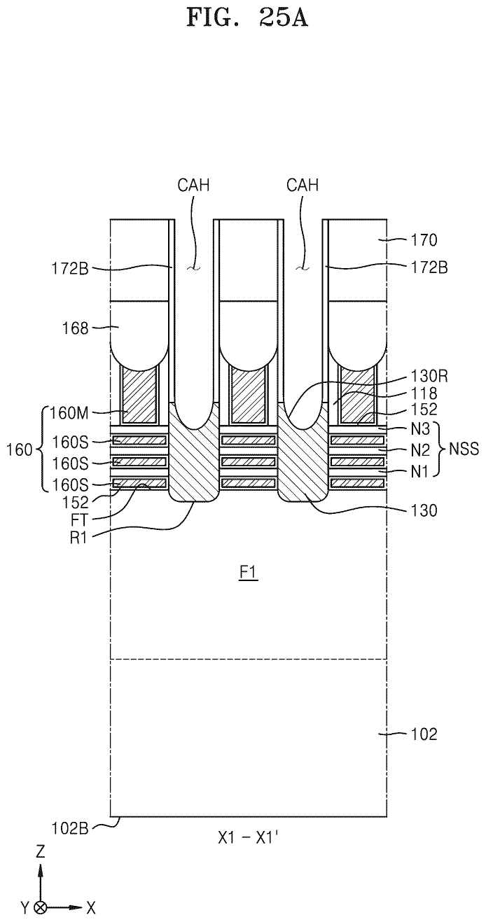

Referring to FIGS. 24A, 24B, and 24C, the third mask pattern MP3 may be removed from the resulting product of FIGS. 23A, 23B, and 23C, thereby exposing the isolation insulating liner 172 around each of the plurality of contact isolation insulating patterns 174. To remove the third mask pattern MP3, ashing and strip processes may be used.

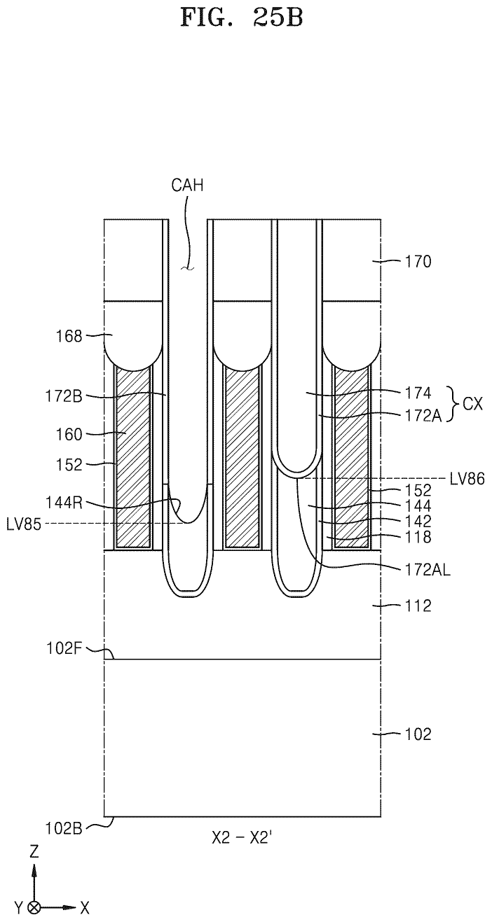

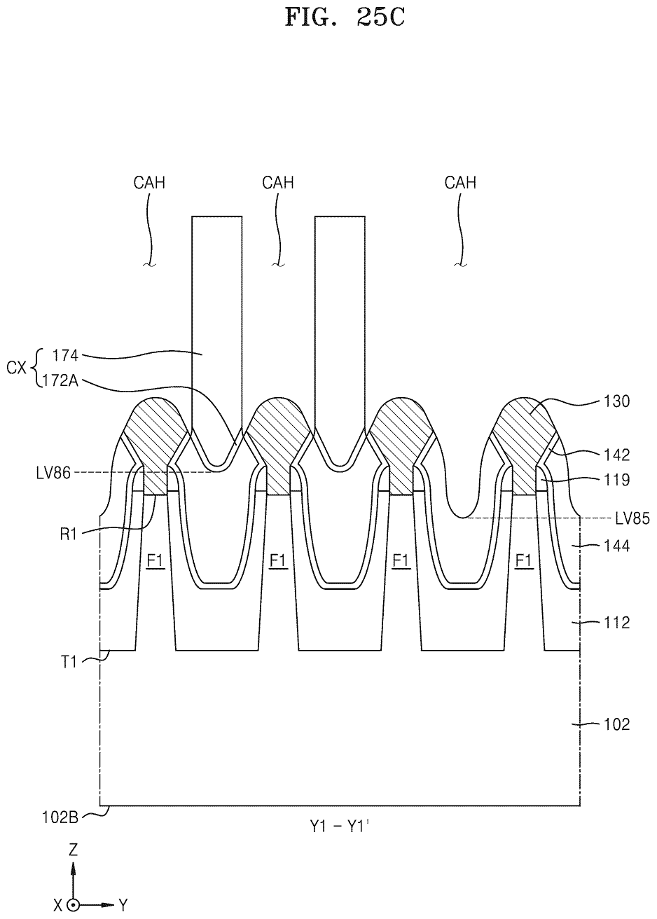

Referring to FIGS. 25A, 25B, and 25C, in the resulting product of FIGS. 24A, 24B, and 24C, portions, which cover the plurality of source/drain regions 130 and the inter-gate dielectric 144, of the isolation insulating liner 172 exposed around each of the plurality of contact isolation insulating patterns 174 may be removed by an anisotropic dry etching process, thereby forming a plurality of source/drain contact holes CAH to expose the plurality of source/drain regions 130, and each of the plurality of source/drain regions 130 exposed by the plurality of source/drain contact holes CAH may be partially etched, thereby forming a recess surface 130R in the upper surface of each of the plurality of source/drain regions 130 on the fin-type active region F1.

While an etching process of the plurality of source/drain regions 130 are being performed to form the recess surface 130R in each of the plurality of source/drain regions 130, a portion of the isolation insulating liner 172 and a portion of the inter-gate dielectric 144, which are exposed to an atmosphere of the etching process, may also be etched together with the plurality of source/drain regions 130. As a result, the upper surface of the first upper insulating film 170 may be exposed, and the recess surface 144R may be formed in the upper surface, which is exposed by the source/drain contact hole CAH, of the inter-gate dielectric 144 over the device isolation film 112.

After the recess surface 130R is formed in the upper surface of each of the plurality of source/drain regions 130 and the recess surface 144R is formed in the upper surface of the inter-gate dielectric 144, portions of the isolation insulating liner 172, which remain over the substrate 102, may include a plurality of first isolation insulating liners 172A and a plurality of second isolation insulating liners 172B. Each of the plurality of first isolation insulating liners 172A may cover a lower surface 174L of the contact isolation insulating pattern 174 (e.g., see FIG. 5) and sidewalls, in the first horizontal direction (the X direction), of the contact isolation insulating pattern 174. The plurality of second isolation insulating liners 172B may respectively cover both inner sidewalls, in the first horizontal direction (the X direction), of the source/drain contact hole CAH.

As shown in FIGS. 25B and 25C, a vertical level LV85 of the lowermost portion of the recess surface 144R of the inter-gate dielectric 144, which is located over the device isolation film 112 and exposed by the source/drain contact hole CAH, may be closer to the substrate 102 and the device isolation film 112 than a vertical level LV86 of the lowermost portion 172AL of the inter-gate dielectric 144, which is located over the device isolation film 112 and contacts the first isolation insulating liner 172A.

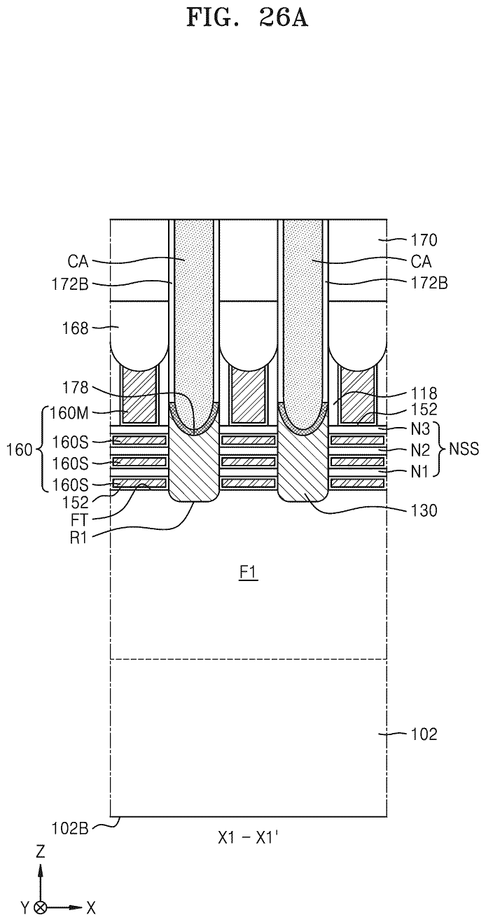

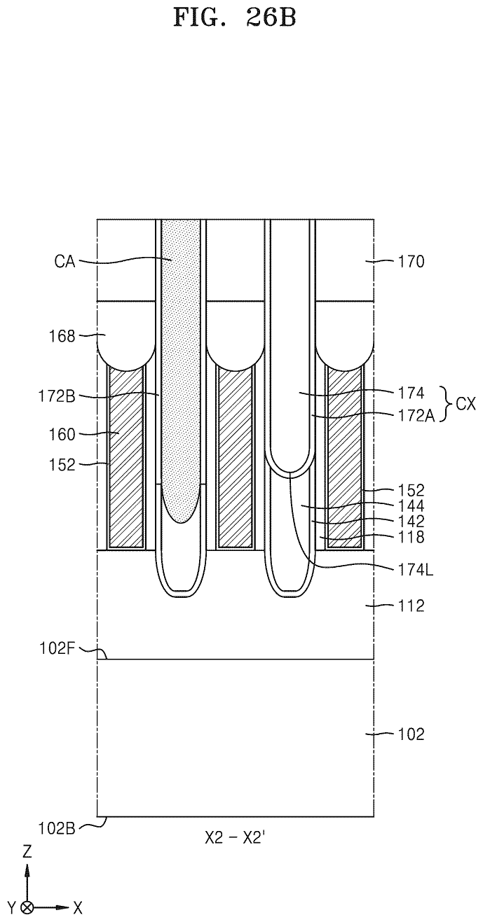

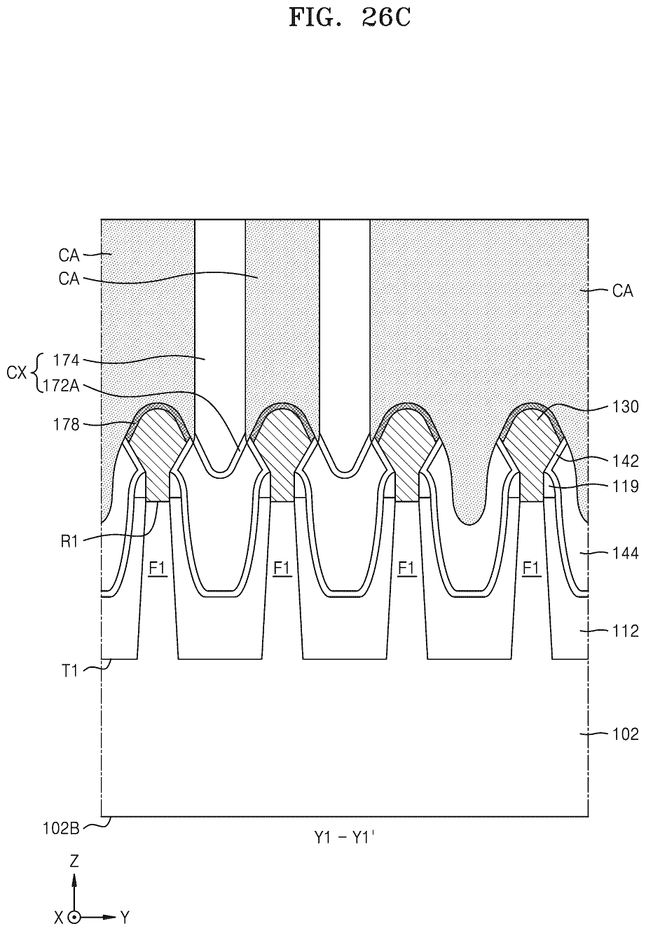

Referring to FIGS. 26A, 26B, and 26C, in the resulting product of FIGS. 25A, 25B, and 25C, the metal silicide film 178 may be formed on respective surfaces of the plurality of source/drain regions 130 exposed by the plurality of source/drain contact holes CAH, and the plurality of source/drain contacts CA may each be formed on the metal silicide film 178 to fill the source/drain contact hole CAH.

Next, as shown in FIGS. 3 to 6, the upper insulating structure 180 may be formed on the resulting product of FIGS. 26A, 26B, and 26C, and the plurality of source/drain via contacts VA, which pass through the upper insulating structure 180 in the vertical direction (the Z direction) to be respectively connected to the plurality of source/drain contacts CA, and the gate contact CB, which passes through the upper insulating structure 180, the first upper insulating film 170, and the capping insulating pattern 168 in the vertical direction (the Z direction) to be connected to the gate line 160, may be formed. The source/drain via contact VA and the gate contact CB may be simultaneously formed or may be separately formed by separate processes from each other. The order of forming the source/drain via contact VA and the gate contact CB is not particularly limited.

Next, the interlayer dielectric 186, which covers the upper insulating structure 180, and the plurality of upper wiring layers M1, which pass through the interlayer dielectric 186, may be formed. The plurality of upper wiring layers M1 may include an upper wiring layer M1 connected to the source/drain via contact VA and an upper wiring layer M1 connected to the gate contact CB. Next, a frontside wiring structure (not shown) may be formed on the interlayer dielectric 186 and the plurality of upper wiring layers M1.

To form the integrated circuit device 300 shown in FIG. 8, in the structure shown in FIGS. 2 to 6, a portion of the substrate 102 may be removed from the backside surface 102B of the substrate 102. To remove the portion of the substrate 102, at least one process selected from a mechanical grinding process, a chemical mechanical polishing (CMP) process, a wet etching process, and a combination thereof may be used. After the portion of the substrate 102 is removed, the backside surface 102B of the substrate 102 may be closer to the device isolation film 112.

Next, a portion of the substrate 102 and a portion of each of the device isolation film 112, the insulating liner 142, and the inter-gate dielectric 144 may be etched in the vertical direction (the Z direction) from the backside surface 102B of the substrate 102, thereby forming a through-region THR to expose at least one source/drain contact CA selected from the plurality of source/drain contacts CA, and the insulating liner 305 and the power rail wiring line MPR may be formed in the through-region THR.

Next, the backside insulating film 309 may be formed on the power rail wiring line MPR and the backside surface 102B of the substrate 102, and the backside power rail BPR may be formed to pass through the backside insulating film 309 in the vertical direction (the Z direction) to be connected to the power rail wiring line MPR. Next, a backside wiring structure (not shown) may be formed on the backside power rail BPR and the backside insulating film 309, as needed, thereby fabricating the integrated circuit device 300 shown in FIG. 8.

Heretofore, although some example embodiments of the methods of fabricating the integrated circuit devices 100 and 300 shown in FIGS. 2 to 6 and 8 have been described with reference to FIGS. 11A to 26C, it will be understood by those of ordinary skill in the art that, by making various modifications and changes to the some example embodiments described with reference to FIGS. 11A to 26C without departing from the spirit and scope of the inventive concepts, the integrated circuit device 200 described with reference to FIGS. 7A and 7B, the integrated circuit device 400 described with reference to FIGS. 9A and 9B, and integrated circuit devices having various structures modified and changed therefrom may be fabricated.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

While the inventive concepts have been particularly shown and described with reference to some example embodiments thereof, it will be understood that various changes in form and details may be made therein without departing from the spirit and scope of the following claims.

What is claimed is:

1. An integrated circuit device comprising:
a first fin-type active region protruding from a substrate and extending in a first horizontal direction;
a first source/drain region on the first fin-type active region;
a first source/drain contact on the first source/drain region and electrically connected to the first source/drain region;
a first contact isolation insulating structure extending along a straight line with the first source/drain contact in a second horizontal direction perpendicular to the first horizontal direction,
the first contact isolation insulating structure comprising a first contact isolation insulating pattern and a first isolation insulating liner, the first contact isolation insulating pattern contacting the first source/drain contact, and the first isolation insulating liner covering sidewalls of the first contact isolation insulating pattern in the first horizontal direction, and the first isolation insulating liner covering a lower surface of the first contact isolation insulating pattern; and
a second isolation insulating liner covering only first sidewalls of the first source/drain contact in the first horizontal direction from among the first sidewalls of the first source/drain contact in the first horizontal direction and second sidewalls of the first source/drain contact in the second horizontal direction,
wherein a constituent material of the first isolation insulating liner and a constituent material of the second isolation insulating liner comprise a same constituent material.

2. The integrated circuit device of claim 1, wherein in the first horizontal direction, a first width of the first source/drain contact is less than a second width of the first contact isolation insulating structure.

3. The integrated circuit device of claim 1, further comprising:
a device isolation film covering sidewalls of the first fin-type active region; and
an insulating structure covering the device isolation film,
wherein the first source/drain contact comprises a lower portion, and in a cross-sectional view of the first source/drain contact taken in the first horizontal direction, a first distance between the lower portion and the device isolation film is less than a second distance between the second isolation insulating liner and the device isolation film, and
the lower portion of the first source/drain contact is over the device isolation film and contacts the insulating structure.

4. The integrated circuit device of claim 1, further comprising:
a device isolation film covering sidewalls of the first fin-type active region; and
an insulating structure covering the device isolation film and a portion of the first source/drain region,
wherein the first isolation insulating liner of the first contact isolation insulating structure contacts the insulating structure at a position overlapping the device isolation film in a vertical direction, and
the first contact isolation insulating pattern of the first contact isolation insulating structure is apart from the insulating structure with the first isolation insulating liner therebetween.

5. The integrated circuit device of claim 4, wherein the first contact isolation insulating structure has a surface facing the insulating structure, and the surface facing the insulating structure has a convex shape toward the device isolation film.

6. The integrated circuit device of claim 1, further comprising a metal silicide film between the first source/drain region and the first source/drain contact,
wherein in a cross-sectional view taken in the second horizontal direction, the first source/drain contact comprises a contact tail between the first source/drain region and the first contact isolation insulating structure, the contact tail extending in a vertical direction toward the substrate along a surface of the first contact isolation insulating structure, and
the metal silicide film comprises a portion between the contact tail and the first source/drain region.

7. The integrated circuit device of claim 1, further comprising:
a second fin-type active region protruding from the substrate and extending in the first horizontal direction parallel to the first fin-type active region;
a second source/drain region on the second fin-type active region, the second source/drain region being apart from the first source/drain region in the second horizontal direction; and
a second source/drain contact on the second source/drain region and electrically connected to the second source/drain region, the second source/drain contact being apart from the first source/drain contact in the second horizontal direction with the first contact isolation insulating structure therebetween,
wherein the first source/drain contact, the first contact isolation insulating structure, and the second source/drain contact extend along the second horizontal direction,
and wherein a first sidewall, in the second horizontal direction, of the first contact isolation insulating pattern of the first contact isolation insulating structure contacts the first source/drain contact, and a second sidewall in the second horizontal direction contacts the second source/drain contact.

8. The integrated circuit device of claim 1, further comprising:
a device isolation film covering sidewalls of the first fin-type active region;
an insulating structure covering the device isolation film;
a gate line over the first fin-type active region and the device isolation film, the gate line extending in the second horizontal direction and intersecting the first fin-type active region;
a second source/drain region on the first fin-type active region and apart from the first source/drain region in the first horizontal direction with the gate line therebetween; and
a second source/drain contact overlapping the second source/drain region and the device isolation film in a vertical direction, the second source/drain contact being electrically connected to the second source/drain region,
wherein a first distance between a lowermost surface of a portion of the second source/drain contact which overlaps the device isolation film in the vertical direction and the device isolation film is less than a second distance between a lowermost surface of a portion of the first contact isolation insulating structure which overlaps the device isolation film in the vertical direction and the device isolation film.

9. The integrated circuit device of claim 8, further comprising a third isolation insulating liner covering only third sidewalls of the second source/drain contact in the first horizontal direction from among the third sidewalls of the second source/drain contact in the first horizontal direction and fourth sidewalls of the second source/drain contact in the second horizontal direction,
wherein a constituent material of the third isolation insulating liner is a same constituent material as the constituent material of each of the first isolation insulating liner and the second isolation insulating liner.

10. The integrated circuit device of claim 1, further comprising:
a gate line over the first fin-type active region, the gate line extending in the second horizontal direction and intersecting the first fin-type active region;
a second source/drain region on the first fin-type active region and apart from the first source/drain region with the gate line therebetween; and
a second contact isolation insulating structure overlapping the second source/drain region in a vertical direction,
wherein a first length in the vertical direction of the second source/drain region on the first fin-type active region is greater than a second length in the vertical direction of the first source/drain region on the first fin-type active region.

11. The integrated circuit device of claim 10, wherein in the vertical direction, a first distance between the second contact isolation insulating structure and the first fin-type active region which are apart from each other with the second source/drain region therebetween, is greater than a second distance between the first source/drain contact and the first fin-type active region which are apart from each other with the first source/drain region therebetween.

12. The integrated circuit device of claim 10, wherein the second contact isolation insulating structure comprises a second contact isolation insulating pattern and a third isolation insulating liner, the second contact isolation insulating pattern being apart from the second source/drain region, and the third isolation insulating liner covering a lower surface of the second contact isolation insulating pattern which faces the second source/drain region and sidewalls of the second contact isolation insulating pattern in the first horizontal direction, and
a constituent material of the third isolation insulating liner is a same constituent material as the constituent material of each of the first isolation insulating liner and the second isolation insulating liner.

13. An integrated circuit device comprising:
a plurality of fin-type active regions protruding from a substrate and extending lengthwise in a first horizontal direction, the plurality of fin-type active regions being apart from each other in a second horizontal direction that is perpendicular to the first horizontal direction;
a plurality of source/drain regions respectively on the plurality of fin-type active regions and aligned in a row on a first straight line extending along the second horizontal direction;
a plurality of source/drain contacts electrically connected to at least one source/drain region from the plurality of source/drain regions, the plurality of source/drain contacts being aligned in a row along the first straight line;
a plurality of contact isolation insulating structures respectively between the plurality of source/drain contacts and aligned in a row along the first straight line,
each of the plurality of contact isolation insulating structures comprising a contact isolation insulating pattern and a first isolation insulating liner, the contact isolation insulating pattern having a sidewall contacting a source/drain contact from among the plurality of source/drain contacts that is adjacent to the contact isolation insulating pattern in the second horizontal direction, and the first isolation insulating liner covering sidewalls of the contact isolation insulating pattern in the first horizontal direction and a lower surface of the contact isolation insulating pattern; and
a plurality of second isolation insulating liners respectively covering only first sidewalls of each of the plurality of source/drain contacts in the first horizontal direction from among the first sidewalls of each of the plurality of source/drain contacts in the first horizontal direction and second sidewalls of each of the plurality of source/drain contacts in the second horizontal direction,
wherein the first isolation insulating liner of each of the plurality of contact isolation insulating structures and each of the plurality of second isolation insulating liners comprise a same constituent material.

14. The integrated circuit device of claim 13, wherein in the first horizontal direction, a width of each of the plurality of source/drain contacts is less than a width of each of the plurality of contact isolation insulating structures.

15. The integrated circuit device of claim 13, wherein sidewalls of the contact isolation insulating pattern of each of the plurality of contact isolation insulating structures in the second horizontal direction contact respective different source/drain contacts from among the plurality of source/drain contacts.

16. The integrated circuit device of claim 13, further comprising a device isolation film covering sidewalls of each of the plurality of fin-type active regions,
wherein the plurality of source/drain contacts and the plurality of contact isolation insulating structures are each apart from the device isolation film in a vertical direction, and
above the device isolation film, a first distance between a lowermost surface of each of the plurality of source/drain contacts and the device isolation film is less than a second distance between a lowermost surface of each of the plurality of contact isolation insulating structures and the device isolation film.

17. An integrated circuit device comprising:
a plurality of fin-type active regions protruding from a substrate and extending lengthwise in a first horizontal direction, the plurality of fin-type active regions being apart from each other in a second horizontal direction that is perpendicular to the first horizontal direction;
a plurality of nanosheet stacks over each of the plurality of fin-type active regions, each of the plurality of nanosheet stacks comprising at least one nanosheet;
a pair of gate lines over the plurality of fin-type active regions and extending lengthwise in the second horizontal direction across the plurality of fin-type active regions parallel to each other, gate lines of the pair of gate lines surrounding the at least one nanosheet of at least one nanosheet stack from the plurality of nanosheet stacks;
a plurality of source/drain regions respectively on the plurality of fin-type active regions between the pair of gate lines, the plurality of source/drain regions being aligned in a row on a first straight line extending along the second horizontal direction;
a plurality of source/drain contacts each electrically connected to at least one source/drain region from the plurality of source/drain regions, the plurality of source/drain contacts being aligned in a row along the first straight line;
a plurality of contact isolation insulating structures respectively between the plurality of source/drain contacts and aligned in a row along the first straight line,
each of the plurality of contact isolation insulating structures comprising a contact isolation insulating pattern and a first isolation insulating liner, the contact isolation insulating pattern having a sidewall contacting a source/drain contact from among the plurality of source/drain contacts that is adjacent to the contact isolation insulating pattern in the second horizontal direction, and the first isolation insulating liner covering sidewalls of the contact isolation insulating pattern in the first horizontal direction and a lower surface of the contact isolation insulating pattern; and
a plurality of second isolation insulating liners respectively covering only first sidewalls of each of the plurality of source/drain contacts in the first horizontal direction from among the first sidewalls of each of the plurality of source/drain contacts in the first horizontal direction and second sidewalls of each of the plurality of source/drain contacts in the second horizontal direction,
wherein the first isolation insulating liner of each of the plurality of contact isolation insulating structures and each of the plurality of second isolation insulating liners comprise a same constituent material, the same constituent material comprising silicon nitride, silicon oxide, SiOC, SiOCN, SiCN, SiBN, SiON, SiBCN, SiOF, SiOCH, or a combination thereof.

18. The integrated circuit device of claim 17, wherein in the first horizontal direction, a width of each of the plurality of source/drain contacts is less than a width of each of the plurality of contact isolation insulating structures.

19. The integrated circuit device of claim 17, wherein sidewalls of the contact isolation insulating pattern of each of the plurality of contact isolation insulating structures in the second horizontal direction contact respective different source/drain contacts from among the plurality of source/drain contacts.

20. The integrated circuit device of claim 17, further comprising:
a device isolation film covering sidewalls of each of the plurality of fin-type active regions; and
an insulating structure covering the plurality of source/drain regions and the device isolation film,
wherein a first contact isolation insulating structure from among the plurality of contact isolation insulating structures, and a first source/drain contact from among the plurality of source/drain contacts, are each in contact with the insulating structure at a position overlapping the device isolation film in a vertical direction and are each apart from the device isolation film in the vertical direction with the insulating structure therebetween, and
a first distance between a lowermost surface of the first source/drain contact and the device isolation film is less than a second distance between a lowermost surface of the first contact isolation insulating structure and the device isolation film.
